(19) United States
(12) Patent Application Publication
(10) Pub. No.: US 2024/0387386 A1
(43) Pub. Date: Nov. 21, 2024

(54) INTERPOSER HAVING FIRST AND SECOND REDISTRIBUTION LAYERS AND METHODS OF MAKING AND USING THE SAME

(71) Applicant: Taiwan Semiconductor Manufacturing Company Limited, Hsinchu (TW)

(72) Inventors: Shang-Yun Hou, Jubei City (TW); Chien-Hsun Lee, Hsinchu (TW); Tsung-Ding Wang, Tainan (TW); Hao-Cheng Hou, Hsinchu City (TW)

(21) Appl. No.: 18/317,121

(22) Filed: May 15, 2023

(51) Int. Cl. H01L 23/538; H01L 21/48; H01L 23/00; H01L 25/00

(52) U.S. Cl. CPC H01L 23/5383; H01L 21/4857; H01L 24/13; H01L 24/16; H01L 24/29; H01L 24/32; H01L 24/73; H01L 24/81; H01L 25/50; H01L 23/49894; H01L 23/5385; H01L 25/18; H01L 2224/13084; H01L 2224/13147; H01L 2224/13155; H01L 2224/16238; H01L 2224/2929; H01L 2224/32225; H01L 2224/73204; H01L 2224/81815; H01L 2924/0665; H10B 80/00

(57) ABSTRACT

An embodiment interposer may include a plurality of first redistribution layers including first electrical interconnect structures having a first line width and a first line spacing embedded in a first dielectric material, and a plurality of second redistribution layers including second electrical interconnect structures having a second line width and a second line spacing embedded in a second dielectric material such that the second line width is greater than the first line width and such that the second line spacing is greater than the first line spacing. The first dielectric material may be one of polyimide, benzocyclobuten, or polybenzo-bisoxazole and second dielectric material may include an inorganic particulate material dispersed in an epoxy resin. The interposer may further include a protective layer, including the second dielectric material, formed over the first redistribution layers, and a surface layer, including the first dielectric material, formed as part of the second redistribution layers.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens, hundreds, or thousands of integrated circuits are typically manufactured on a single semiconductor wafer, and individual dies on the wafer are singulated by sawing between the integrated circuits along scribe lines. The individual dies are typically packaged separately, in multi-chip modules, or in other types of packaging, for example.

In addition to ongoing efforts in the pursuit of ever smaller electronic components, continuing improvements in the packaging of components are providing smaller packages that occupy less area than previous packages. Example approaches include quad flat pack (QFP), pin grid array (PGA), ball grid array (BGA), flip chips (FC), 3-dimensional integrated circuits (3DICs), wafer level packages (WLPs), package on package (POP), System on Chip (SoC) or System on Integrated Circuit (SoIC) devices. Some of these 3-dimensional devices (e.g., 3DIC, SoC, SoIC) are prepared by placing chips over chips on a semiconductor wafer level. These 3-dimensional devices provide improved integration density and other advantages, such as faster speeds and higher bandwidth, due to decreased length of interconnects between the stacked chips. However, there are many challenges related to the fabrication and operation of 3-dimensional devices including mechanical issues related to thermal expansion mismatch between package components leading to warpage, cracking, delamination, etc.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is vertical cross-sectional exploded view of components of a semiconductor package during a package assembly and surface mounting process.

FIG. 1B is a vertical cross-sectional view illustrating an assembled semiconductor package mounted onto the surface of a support substrate.

FIG. 2 is a vertical cross-sectional view of a further semiconductor package illustrating electrical interconnect structures of a package substrate.

FIG. 3 is a vertical cross-sectional view of a further semiconductor package including an interposer having a first plurality of redistribution layers and a second plurality of redistribution layers, according to various embodiments.

FIG. 4A is a vertical cross-sectional view of the package substrate of the semiconductor package of FIG. 2.

FIG. 4B is a vertical cross-sectional view of a package substrate of the semiconductor package of FIG. 3, according to various embodiments.

FIG. 5 is a vertical cross-sectional view of an intermediate structure that may be used to form a semiconductor package, according to various embodiments.

FIG. 6 is a vertical cross-sectional view of a further intermediate structure that may be used to form a semiconductor package, according to various embodiments.

FIG. 7 is a vertical cross-sectional view of a further intermediate structure that may be used to form a semiconductor package, according to various embodiments.

FIG. 8 is a vertical cross-sectional view of a further intermediate structure that may be used to form a semiconductor package, according to various embodiments.

FIG. 9 is a vertical cross-sectional view of a further intermediate structure that may be used to form a semiconductor package, according to various embodiments.

FIG. 10 is a vertical cross-sectional view of a further intermediate structure that may be used to form a semiconductor package, according to various embodiments.

FIG. 11 is a vertical cross-sectional view of a further intermediate structure that may be used to form a semiconductor package, according to various embodiments.

FIG. 12 is a vertical cross-sectional view of a further intermediate structure that may be used to form a semiconductor package, according to various embodiments.

FIG. 13 is a vertical cross-sectional view of a further intermediate structure that may be used to form a semiconductor package, according to various embodiments.

FIG. 14 is a vertical cross-sectional view of a further intermediate structure that may be used to form a semiconductor package, according to various embodiments.

FIG. 15 is a vertical cross-sectional view of a further intermediate structure that may be used to form a semiconductor package, according to various embodiments.

FIG. 16 is a vertical cross-sectional view of a further intermediate structure that may be used to form a semiconductor package, according to various embodiments.

FIG. 17 is a vertical cross-sectional view of a further intermediate structure that may be used to form a semiconductor package, according to various embodiments.

FIG. 18 is a vertical cross-sectional view of a further intermediate structure that may be used to form a semiconductor package, according to various embodiments.

FIG. 19A is a vertical cross-sectional view of an embodiment semiconductor package, according to various embodiments.

FIG. 19A is a vertical cross-sectional view of a further embodiment semiconductor package, according to various embodiments.

FIG. 20 is a vertical cross-sectional view of a further intermediate structure that may be used to form a semiconductor package, according to various embodiments.

FIG. 21 is a vertical cross-sectional view of a further intermediate structure that may be used to form a semiconductor package, according to various embodiments.

FIG. 22 is a vertical cross-sectional view of a further embodiment semiconductor package that may be formed from the intermediate structures of FIGS. 21 and 22, respectively.

FIG. 23 is a flowchart illustrating various operations of a method of forming an interposer, according to various embodiments.

### DETAILED DESCRIPTION

The following disclosure provides many different embodiments, or examples, for implementing various features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, this disclosure may repeat reference numerals and/or letters in the disclosed example embodiments. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Typically, in a semiconductor package, a number of semiconductor integrated circuit (IC) dies (i.e., “chips”) may be mounted onto a common substrate. The common substrate, on which the chips may be mounted, may also be referred to as a “package substrate.” In some embodiments, electrical connections to the semiconductor package may be made by mounting the package substrate onto a support substrate containing electrical interconnects, such as a printed circuit board (PCB).

An interposer may be advantageous to include in the semiconductor package as the interposer may provide a plurality of first redistribution layers and a plurality of second redistribution layers. The first redistribution layers may include first electrical interconnect structures having a fine line width and spacing that may be configured to provide high-speed die-to-die communication channels between a first semiconductor die and a second semiconductor die in a semiconductor package, while the plurality of second redistribution layers may include second electrical interconnect structures that may be configured to provide enhanced power delivery channels relative to those of alternative interposers. Each of the plurality of first redistribution layers and the plurality of second redistribution layers may be formed in one or more polymer materials that may allow increased elastic deformation that may thereby reduce thermal stresses/strains between components of a semiconductor package and may thus mitigate issues related to thermal-induced deformation, warpage, cracking, delamination, etc. The plurality of first redistribution layers may also provide some of the functionality otherwise provided by alternative interposers and the plurality of second redistribution layers may provide some of the functionality otherwise provided by a package substrate. As such, a package substrate used in conjunction with the various embodiment interposers may require fewer interconnect layers thus leading to an overall reduction in the complexity of the semiconductor package relative to existing package structures.

An embodiment interposer may include a plurality of first redistribution layers including first electrical interconnect structures having a first line width and a first line spacing embedded in a first dielectric material, and a plurality of second redistribution layers including second electrical interconnect structures having a second line width and a second line spacing embedded in a second dielectric material such that the second line width is greater than the first line width and such that the second line spacing is greater than the first line spacing. The first dielectric material may be one of polyimide, benzocyclobuten, or polybenzo-bisoxazole and second dielectric material may include an inorganic particulate material dispersed in an epoxy resin. The interposer may further include a protective layer, including the second dielectric material, formed over the first redistribution layers, and a surface layer, including the first dielectric material, formed as part of the second redistribution layers.

In a further embodiment, a semiconductor package is provided. The semiconductor package may include an interposer having a slab geometry with a first surface and a second surface. The interposer may further include a plurality of first redistribution layers including first electrical interconnect structures formed in a first dielectric material proximate to the first surface and a plurality of second redistribution layers including second electrical interconnect structures formed in a second dielectric material proximate to the second surface. According to an embodiment, the first dielectric material may have greater elasticity than the second dielectric material. The plurality of second redistribution layers may further include a surface layer including the first dielectric material formed proximate to the second surface of the interposer such that the surface layer partially surrounds the second electrical interconnect structures.

In a further embodiment, a method of forming an interposer is provided. The method may include forming a plurality of first redistribution layers over a first carrier substrate and forming a plurality of second redistribution layers over the plurality of first redistribution layers. The plurality of first redistribution layers may include first electrical interconnect structures having a first line width and a first line spacing embedded in a first dielectric material and the plurality of second redistribution layers may include second electrical interconnect structures having a second line width and a second line spacing embedded in a second dielectric material. In various embodiments, the second line width may be greater than the first line width and the second line spacing may be greater than the first line spacing.

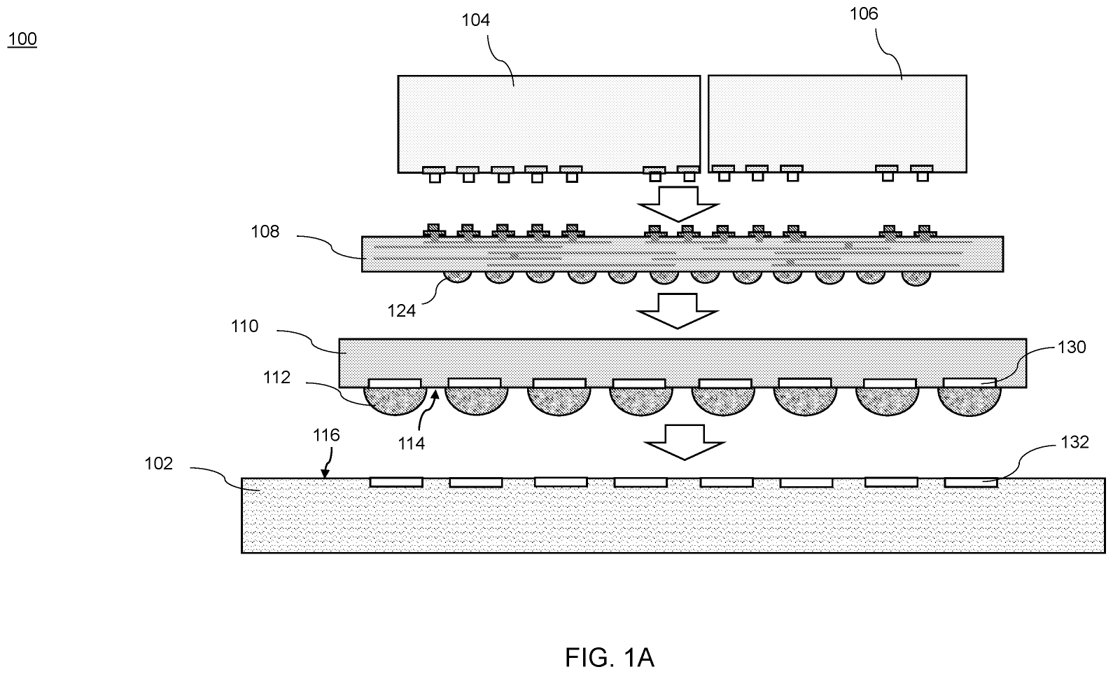

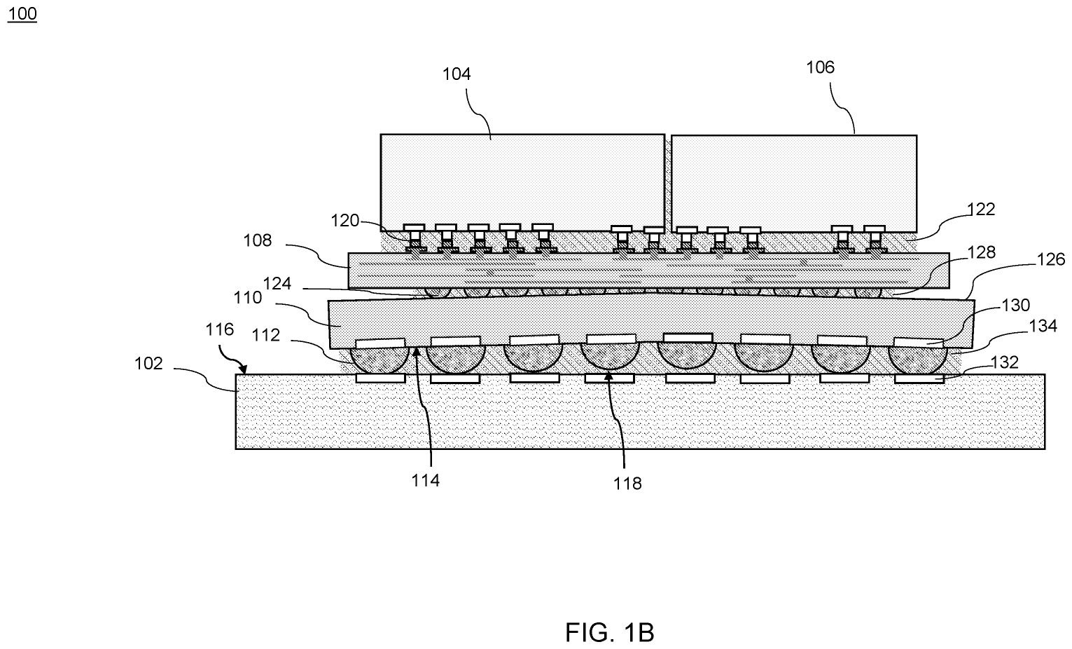

FIG. 1A is vertical cross-section exploded view of components of a semiconductor package 100 during a package assembly and surface mounting process. FIG. 1B is a vertical cross-section view illustrating the assembled semiconductor package 100 mounted onto the surface of a support substrate 102, such as a printed circuit board (PCB). The semiconductor package 100 in this example is a chip-on-wafer-on-substrate (CoWoS)® semiconductor package, although it will be understood that a similar assembly and mounting process may be utilized for other types of semiconductor packages, such as integrated fan-out (InFO) semiconductor packages, flip-chip semiconductor packages, etc.

Referring to FIGS. 1A and 1B, the package 100 may include integrated circuit (IC) semiconductor dies, such as first semiconductor dies 104 and second semiconductor dies 106. During the package assembly process, the first semiconductor die 104 and the second semiconductor die 106 may be mounted to an interposer 108, and the interposer 108 may be mounted onto a package substrate 110 to form a semiconductor package 100. The semiconductor package 100 may then be mounted to a support substrate 102, such as a printed circuit board (PCB), by mounting the package substrate 110 to the support substrate 102 using an array of solder balls 112 on the lower surface 114 of the package substrate 110.

A parameter that may ensure proper interconnection between the package substrate 110 and the support substrate 102 is the degree of co-planarity between the surfaces of the solder balls 112 that may be brought into contact with the mounting surface (i.e., the upper surface 116 of the support substrate 102 in FIG. 1A). A low degree of co-planarity between the solder balls 112 may result in instances of solder cold joints (i.e., insufficient melting of the solder material, resulting in a poor bond that is susceptible to cracking and separation) and/or solder bridging issues (i.e., solder material from one solder ball 112 contacting material from a neighboring solder ball 112, resulting in an unintended connection (i.e., electrical short)) during a reflow process.

Deformation of the package substrate 110, such as stress-induced warping of the package substrate 110, may be a contributor to low co-planarity of the solder balls 112 during surface mounting of the package substrate 110 onto a support substrate 102. FIG. 1B illustrates a package substrate 110 that includes a warpage deformation. The warpage deformation of the package substrate 110 may result in variations of the distance between the lower surface 114 of the package substrate 110 and the upper surface 116 support substrate 102. Such deformation of the package substrate 110 may increase the risk of defective solder connections with the underlying support substrate 102. As shown in FIG. 1B, for example, a deformation of the package substrate 110 may cause at least some of the solder joints between the package substrate 110 and the support substrate 102 to fail completely, as indicated by the arrow 118 in FIG. 1B. In the exemplary embodiment shown in FIG. 1B, the deformation of the package substrate 110 may have a bow-shape or cup-shape such that a separation between the lower surface 114 of the package substrate 110 and the upper surface 116 of the support substrate 102 may be smallest at the periphery of the package substrate 110 and may increase towards the center of the package substrate 110.

Deformation of the package substrate 110 is not an uncommon occurrence, particularly in the case of semiconductor packages used in high-performance computing applications. These high-performance semiconductor packages 100 tend to be relatively large and may include a number of semiconductor dies (e.g., 104, 106) mounted to the package substrate 110. The thermal load generated by such semiconductor dies (e.g., 104, 106) and the differences in coefficients of thermal expansion (CTE) often results in warpage and other deformations of the package substrate 110 and other components of the semiconductor package 100. Such deformations may present challenges to effective solder mounting of these types of semiconductor package substrates 110 onto a support substrate 102.

In various embodiments, the first semiconductor dies 104 may be three-dimensional devices, such as three-dimensional integrated circuits (3DICs), System on Chip (SOC) or System on Integrated Circuit (SoIC) devices. A three-dimensional semiconductor device may be formed by placing chips over chips on a semiconductor wafer level. These three-dimensional devices may provide improved integration density and other advantages, such as faster speeds and higher bandwidths, due to a decreased length of interconnects between the stacked chips. In some embodiments, a first three-dimensional semiconductor device may also be referred to as a “first die stack.”

The second semiconductor device(s) 106 may be different from the first semiconductor device(s) 104 in terms of their structure, design and/or functionality. The one or more second semiconductor dies 106 may be three-dimensional semiconductor dies, which may also be referred to as “second die stacks.” In some embodiments, the one or more second semiconductor dies 106 may include a memory device, such as a high bandwidth memory (HBM) device. In the example shown in FIGS. 1A and 1B, the semiconductor package 100 may include a SOC die stack 104 and an HBM die stack 106, although it will be understood that the semiconductor package 100 may include greater or fewer numbers of semiconductor dies.

Referring again to FIG. 1B, the first semiconductor dies 104 and second semiconductor dies 106 may be mounted on an interposer 108. In some embodiments, the interposer 108 may be an organic interposer including a polymer dielectric material (e.g., a polyimide material) having a plurality of metal interconnect structures extending therethrough. In other embodiments, the interposer 108 may be a semiconductor interposer, such as a silicon interposer, having a plurality of interconnect structures (e.g., through-silicon vias) extending therethrough. Other suitable configurations for the interposer 108 are within the contemplated scope of the disclosure. The interposer 108 may include a plurality of conductive bonding pads (not shown) on upper and lower surfaces of the interposer and a plurality of conductive interconnects extending through the interposer 108 between the upper and lower bonding pads of the interposer 108. The conductive interconnects may distribute and route electrical signals between the first semiconductor dies 104, the second semiconductor dies 106, and the underlying package substrate 110. Thus, the interposer 108 may also be referred to as a redistribution layer (RDL).

A plurality of metal bumps 120, such as microbumps, may electrically connect conductive bonding pads on the bottom surfaces of the first semiconductor dies 104 and second semiconductor dies 106 to the conductive bonding pads on the upper surface of the interposer 108. In one non-limiting embodiment, metal bumps 120 in the form of microbumps may include a plurality of first metal stacks, such as a plurality of Cu—Ni—Cu stacks, located on the bottom surfaces of the first semiconductor dies 104 and second semiconductor dies 106, and a plurality of second metal stacks (e.g., Cu—Ni—Cu stacks) located on the upper surface of the interposer 108. A solder material, such as tin (Sn), may be located between respective first and second metal stacks to electrically connect the first semiconductor dies 104 and the second semiconductor dies 106 to the interposer 108. Other suitable materials for the metal bumps 120 are within the contemplated scope of disclosure.

After the first semiconductor dies 104 and second semiconductor dies 106 are mounted to the interposer 108, a first underfill material portion 122 may optionally be provided in the spaces surrounding the metal bumps 120 and between the bottom surfaces of the first semiconductor dies 104, the second semiconductor dies 106, and the upper surface of the interposer 108 as shown in FIG. 1B. The first underfill material portion 122 may also be provided in the spaces laterally separating adjacent first semiconductor dies 104 and second semiconductor dies 106 of the semiconductor package 100. In various embodiments, the first underfill material portion 122 may include an epoxy-based material, which may include a composite of resin and filler materials.

Referring again to FIG. 1B, the interposer 108 may be mounted on the package substrate 110 that may provide mechanical support for the interposer 108 and the first semiconductor dies 104 and second semiconductor dies 106 that are mounted on the interposer 108. The package substrate 110 may include a suitable material, such as an organic material (e.g., a polymer and/or thermoplastic material), a semiconductor material (e.g., a semiconductor wafer, such as a silicon wafer), a ceramic material, a glass material, combinations thereof, or the like. Other suitable substrate materials are within the contemplated scope of this disclosure. In various embodiments, the package substrate 110 may include a plurality of conductive bonding pads (not shown) in an upper surface 126 of the package substrate 110. A plurality of metal bumps 124, such as C4 solder bumps, may electrically connect conductive bonding pads (not shown) on the bottom surface of the interposer 108 to the conductive bonding pads on the upper surface 126 of the package substrate 110. In various embodiments, the metal bumps 124 may include a suitable solder material, such as tin (Sn), although other suitable solder materials are within the contemplated scope of disclosure.

A second underfill material portion 128 may be provided in the spaces surrounding the metal bumps 124 and between the bottom surface of the interposer 108 and the upper surface 126 of the package substrate 110 as illustrated, for example, in FIG. 1B. In various embodiments, the second underfill material portion 128 may include an epoxy-based material, which may include a composite of resin and filler materials. In some embodiments, a lid or cover (not shown in FIGS. 1A and 1B) may be mounted to the package substrate 110 and may provide an enclosure around the upper and side surfaces of the first semiconductor dies 104 and second semiconductor dies 106.

As described above, the package substrate 110 may be mounted to the support substrate 102, such as a printed circuit board (PCB). Other suitable support substrates 102 are within the contemplated scope of disclosure. The package substrate 110 may include a plurality of conductive bonding pads 130 in a lower surface 114 of the package substrate 110. A plurality of conductive interconnects (not shown) may extend through the package substrate 110 between conductive bonding pads on the upper surface 126 and lower surface 114 of the package substrate 110. The plurality of solder balls (or bump structures) 112 may electrically connect the conductive bonding pads 130 on the lower surface 114 of the package substrate 110 to a plurality of conductive bonding pads 132 on the upper surface 116 of the support substrate 102.

The conductive bonding pads 130 of the package substrate 110 and conductive bonding pads 132 of the support substrate 102 may be formed of a suitable conductive material, such as copper. Other suitable conductive materials are within the contemplated scope of disclosure. The plurality of solder balls 112 on the lower surface 114 of the package substrate 110 may form an array of solder balls 112, such as a ball grid array (BGA) that may include an array pattern that corresponds to an array pattern of the conductive bonding pads 132 on the upper surface 116 of the support substrate 102. In one non-limiting example, the array of solder balls 112 may include a grid pattern and may have a pitch (i.e., distance between the center of each solder ball 112 and the center of each adjacent solder ball 112). In an example embodiment, the pitch may be between about 0.8 and 1.0 mm, although larger and smaller pitches may be used.

The solder balls 112 may include any suitable solder material, such as tin, lead, silver, indium, zinc, nickel, bismuth, antimony, cobalt, copper, germanium, alloys thereof, combinations thereof, or the like. Other suitable materials for the solder balls 112 are within the contemplated scope of disclosure. In some embodiments, the lower surface 114 of the package substrate 110 may include a coating of solder resist (SR) material (not shown), which may also be referred to as a “solder mask”. A SR material coating may provide a protective coating for the package substrate 110 and any underlying circuit patterns formed on or within the package substrate 110. An SR material coating may also inhibit solder material from adhering to the lower surface 114 of the package substrate 110 during a reflow process. In embodiments in which the lower surface 114 of the package substrate 110 includes an SR coating, the SR material coating may include a plurality of openings through which the conductive bonding pads 130 may be exposed.

In various embodiments, each of the conductive bonding pads 130 in different regions of the package substrate 110 may have the same size and shape. In the embodiment shown in FIGS. 1A and 1B, the surfaces of the conductive bonding pads 130 may be substantially co-planar with the lower surface 114 of the package substrate 110, which in some embodiments may include a solder resist (SR) coating. Alternatively, the surfaces of the conductive bonding pads 130 may be recessed relative to the lower surface 114 of the package substrate 110. In some embodiments, the surfaces of the conductive bonding pads 130 may be raised relative to the lower surface 114 of the package substrate 110.

Referring again to FIGS. 1A and 1B, solder balls 112 may be provided over the respective conductive bonding pads 130. In one non-limiting example, the conductive bonding pads 130 may have a width dimension that is between about 500 μm and about 550 μm (e.g., ˜530 μm), and the solder balls 112 may have an outer diameter that may be between about 600 μm and about 650 μm (e.g., ˜ 630 μm), although larger and smaller sizes for the solder balls 112 and/or the conductive bonding pads 130 are within the contemplated scope of disclosure.

A first solder reflow process may include subjecting the package substrate 110 to an elevated temperature (e.g., at least about 250° C.) to melt the solder balls 112 and cause the solder balls 112 to adhere to the conductive bonding pads 130. Following the first reflow process, the package substrate 110 may be cooled causing the solder balls 112 to re-solidify. Following the first solder reflow process, the solder balls 112 may adhere to the conductive bonding pads 130. Each solder ball 112 may extend from the lower surface 114 of the package substrate 110 by a vertical height that may be less than the outer diameter of the solder ball 112 prior to the first reflow process. For example, in instances in which the outer diameter of the solder ball 112 is between about 600 μm and about 650 μm (e.g., ˜630 μm), the vertical height of the solder ball 112 following the first reflow process may be between about 500 μm and about 550 μm (e.g., ˜ 520 μm).

In various embodiments, the process of mounting the package substrate 110 onto the support substrate 102 as shown in FIG. 1B, may include aligning the package substrate 110 over the support substrate 102, such that the solder balls 112 contacting the conductive bonding pads 130 of the package substrate 110 may be located over corresponding bonding pads (e.g., conductive bonding pads 132) on the support substrate 102. A second solder reflow process may then be performed. The second solder reflow process may include subjecting the package substrate 110 to an elevated temperature (e.g., at least about 250° C.) to thereby melt the solder balls 112 and to cause the solder balls 112 to adhere to the corresponding conductive bonding pads 132 on the support substrate 102. Surface tension may cause the semi-liquid solder to maintain the package substrate 110 in alignment with the support substrate 102 while the solder material cools and solidifies. Upon solidification of the solder balls 112, the package substrate 110 may be positioned above the upper surface 116 of the support substrate 102 by a stand-off distance that may be between approximately 0.4 mm to 0.5 mm, in some embodiments, although larger or smaller stand-of heights are within the contemplated scope of disclosure.

Following the mounting of the package substrate 110 to the surface substrate 102, a third underfill material portion 134 may be provided in the spaces surrounding the solder balls 112 and between the lower surface 114 of the package substrate 110 and the upper surface 116 of the support substrate 102, as shown in FIG. 1B. In various embodiments, the third underfill material portion 134 may include an epoxy-based material, which may include a composite of resin and filler materials.

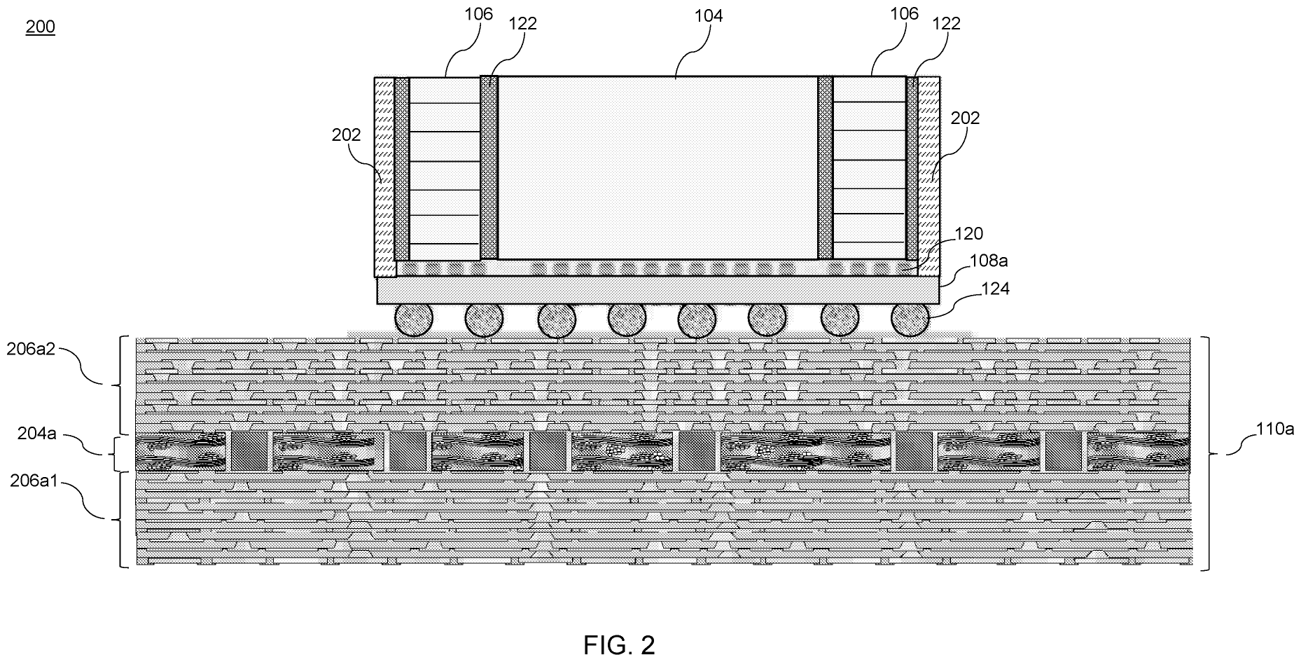

FIG. 2 is a vertical cross-sectional view of a further semiconductor package 200 illustrating electrical interconnect structures (206a1, 206a2) of a first package substrate 110a. The semiconductor package 200 may be similar to the semiconductor package 100 of FIGS. 1A and 1B. In this regard, the semiconductor package 200 may include a first semiconductor die 104 and two second semiconductor dies 106 mounted to a first interposer 108a. The first interposer 108a may be mounted to a first package substrate 110a, as described above with reference to FIGS. 1A and 1B. The semiconductor package 200 may include a first underfill material portion 122 provided in the spaces laterally separating the adjacent first semiconductor die 104 and second semiconductor dies 106 of the semiconductor package 200.

The semiconductor package 200 may further include an epoxy molding compound (EMC) that may be applied to gaps formed between the first interposer 108a, the first semiconductor die 104, and the second semiconductor die 106, to thereby form a multi-die EMC frame 202. The EMC material may include an epoxy-containing compound that may be hardened (i.e., cured) to provide a dielectric material portion having sufficient stiffness and mechanical strength. The EMC material may include epoxy resin, hardener, silica (as a filler material), and other additives. The EMC material may be provided in a liquid form or in a solid form depending on the viscosity and flowability.

Liquid EMC may provide better handling, good flowability, fewer voids, better fill, and fewer flow marks. Solid EMC may provide less cure shrinkage, better stand-off, and less die drift. A high filler content (such as 85% in weight) within an EMC material may shorten the time in mold, lower the mold shrinkage, and reduce the mold warpage. A uniform filler size distribution in the EMC material may reduce flow marks and may enhance flowability. The curing temperature of the EMC material may be in a range from 125° C. to 150° C. The EMC frame 202 may be cured at a curing temperature to form an EMC matrix that laterally encloses each of the first semiconductor die 104 and the second semiconductor die 106. Excess portions of the EMC frame 202 may be removed from above the horizontal plane including the top surfaces of the semiconductor dies (104, 106) by a planarization process, such as CMP.

The semiconductor package 200 of FIG. 2 may be configured as a CoWoS device in which the first semiconductor die 104 may be configured as a SoC die and the second semiconductor dies 106 may each be configured as a HBM die. In this regard, the first semiconductor die 104 may include a central processing unit (CPU), memory interfaces, on-chip input/output devices, input/output interfaces, and secondary storage interfaces, alongside other components such as radio modems and/or a graphics processing unit (GPU). The first semiconductor die 104 may further contain digital, and also analog, mixed-signal, and/or radio frequency signal processing functions. Each of the second semiconductor dies 106 may be configured as a high-speed computer memory interface for 3D-stacked synchronous dynamic random-access memory (SDRAM). For example, in some embodiments, the second semiconductor dies 104 may include a stack of up to eight DRAM dies and an optional base die which may include buffer circuitry and test logic.

The stack may be connected to a memory controller on a GPU or CPU through a substrate, such as the first interposer 108a. Alternatively, in other embodiments, the second semiconductor dies 106 may be stacked directly on a CPU or GPU chip (not shown). Within the stack, the DRAM dies may be vertically interconnected by through-silicon vias (TSVs) and microbumps (also not shown). In one embodiment, the first interposer 108a may be a silicon interposer that may provide finely-spaced interconnect structures (not shown) that may allow short, fast, electrical communication pathways among the first semiconductor die 104 and the second semiconductor dies 106.

As shown in FIG. 2, the first package substrate 110a may include a core structure 204a and various interconnect structures (206a1, 206a2). For example, the first package substrate 110a may include a first interconnect structure 206a1 formed below the core structure 204a and a second interconnect structure 206a2 formed above the core structure 204a. In this example, the core structure 204a may include two layers of electrical interconnects, while the first interconnect structure 206al and the second interconnect structure 206a2 may each include nine layers of electrical interconnects. Other numbers of interconnect layer may be provided in other embodiments. The core structure 204a may include electrical interconnects formed in a fiber-reinforced composite material and the first interconnect structure 206al and the second interconnect structure 206a2 may each include electrical interconnects formed in a polymer material.

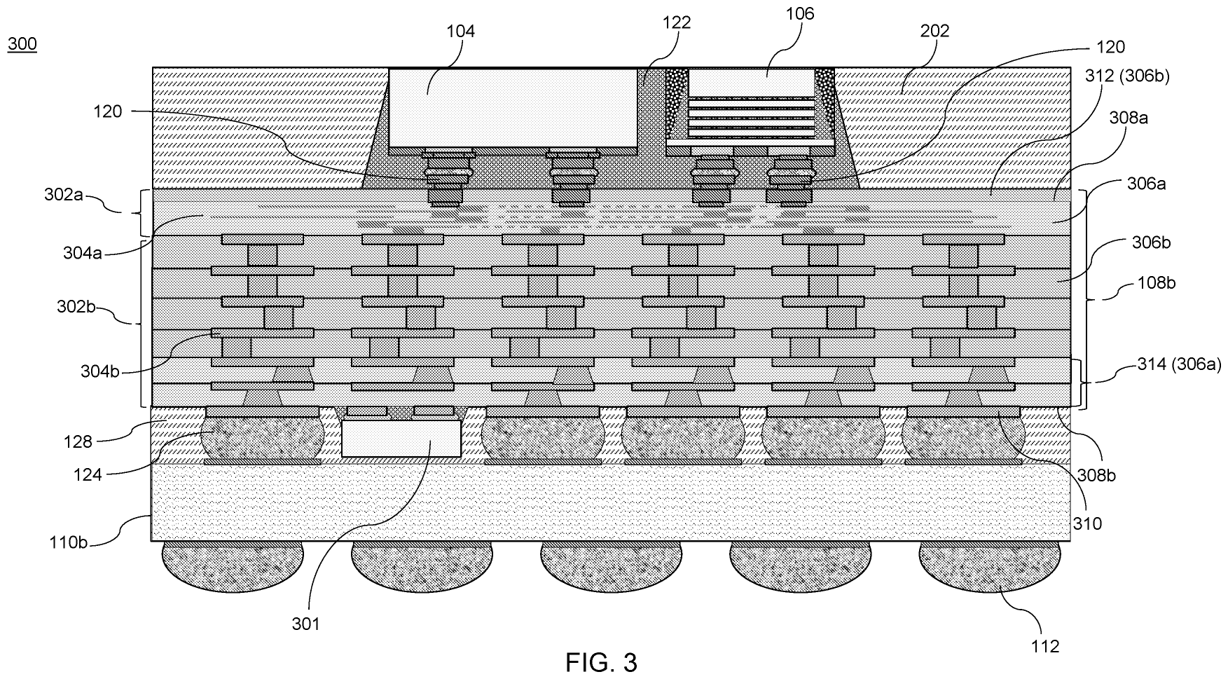

The interconnect layers in the first package substrate 110a may provide electrical routing from the semiconductor dies (104, 106) to a support substrate 102 (e.g., see FIGS. 1A and 1B). As described above with reference to FIGS. 1A and 1B various mechanical distortions and degradations may occur in the semiconductor package 200 due to disparities in relative size, mechanical properties, and thermal expansion coefficients of the various components of the semiconductor package 200. In this regard, thermal stresses/strains generated between the first semiconductor die 104, the second semiconductor dies 104, the silicon first interposer 108a, and the first package substrate 110a may lead to delamination/cracking of the first underfill material portion 122 and the multi-die EMC frame 202, cracking of metal bumps (120, 124), etc. Further, under certain circumstances, surface roughness of the second interconnect structure 206a2 may lead to mechanically weak and/or inferior electrical connections between the first package substrate 110a and the first interposer 108a that may lead to short/open circuit phenomena and/or insertion losses, especially at high signal frequencies. Various embodiment interposer structures (e.g., second interposer 108b) may mitigate some or all of these issues, as described in greater detail with reference to FIGS. 3 to 22, below.

FIG. 3 is further semiconductor package 300 including a second interposer 108b having a plurality of first redistribution layers 302a and a plurality of second redistribution layers 302b, according to various embodiments. The semiconductor package 300 may include a first semiconductor die 104 and a second semiconductor die 106 electrically and mechanically connected to the second interposer 108b by a plurality of metal bumps 120 (e.g., microbumps). The semiconductor package 300 may include a first underfill material portion 122 provided in the spaces laterally separating the first semiconductor die 104 and second semiconductor die 106, and a multi-die EMC frame 202 partially surrounding the first semiconductor die 104 and the second semiconductor die 106. The second interposer 108b may be electrically and mechanically connected to a second package substrate 110b with a plurality of metal bumps 124 (e.g., C4 solder bumps). A second underfill material portion 128 may be provided in the spaces surrounding the metal bumps 124 and between a bottom surface of the second interposer 108b and an upper surface of the second package substrate 110b. The second package substrate 110b may further include a plurality of solder balls (or bump structures) 112 such that the second package substrate 110b may be electrically and mechanically connected to a support substrate 102 (e.g., see FIG. 1B). As shown in FIG. 3, one or more integrated passive devices 301 may also be electrically and mechanically attached to the second interposer 108b.

As in the example semiconductor package 200 of FIG. 2, the semiconductor package 300 may be configured as a CoWoS device in which the first semiconductor die 104 may be configured as a SoC die and the second semiconductor die 106 may be configured as an HBM die. Unlike the semiconductor package 200 of FIG. 2, however, the second interposer 108b of FIG. 3 may have different electrical and mechanical properties from those of the silicon first interposer 108a of the semiconductor package 200 of FIG. 2. In this regard, each of the plurality of first redistribution layers 302a and the plurality of second redistribution layers 302b may be formed in one or more polymer materials that may allow increased elastic deformation, in contrast to the silicon first interposer 108a of the semiconductor package 200. The increased elastic deformation may thereby reduce thermal stresses/strains between the second interposer 108b and the second package substrate 110b and between the second interposer 108b and other components of the semiconductor package 300 including the first semiconductor die 104, the second semiconductor die 106, and the EMC frame 202. As such, the second interposer 108b of FIG. 3 may mitigate issues related to thermal-induced deformation, warpage, cracking, delamination, etc.

The plurality of first redistribution layers 302a may include first electrical interconnect structures 304a having a fine line width and spacing, and the plurality of second redistribution layers 302b may include second electrical interconnect structures 304b having a larger line width and spacing. In this regard, the first electrical interconnect structures 304a may have a first line width that is between 1 micron and 5 microns and a first line spacing is between 1 micron and 5 microns. The second electrical interconnect structures 304b may have a second line width that is between 8 microns and 50 microns a second line spacing that is between 8 microns and 50 microns. In various embodiments, the first electrical interconnect structures 304a may include a first thickness that is between 1 micron to 5 microns and the second electrical interconnect structures 304b may include a second thickness that is between 5 microns and 18 microns. In various embodiments, the plurality of first redistribution layers 302a may include two to six layers of first electrical interconnect structures 304a embedded in the first dielectric material 306a and the plurality of second redistribution layers 302b may include four to eight layers of second electrical interconnect structures 304b embedded in the second dielectric material 306b. Other embodiments may include various other numbers of layers of the first electrical interconnect structures 304a and the second electrical interconnect structures 304b.

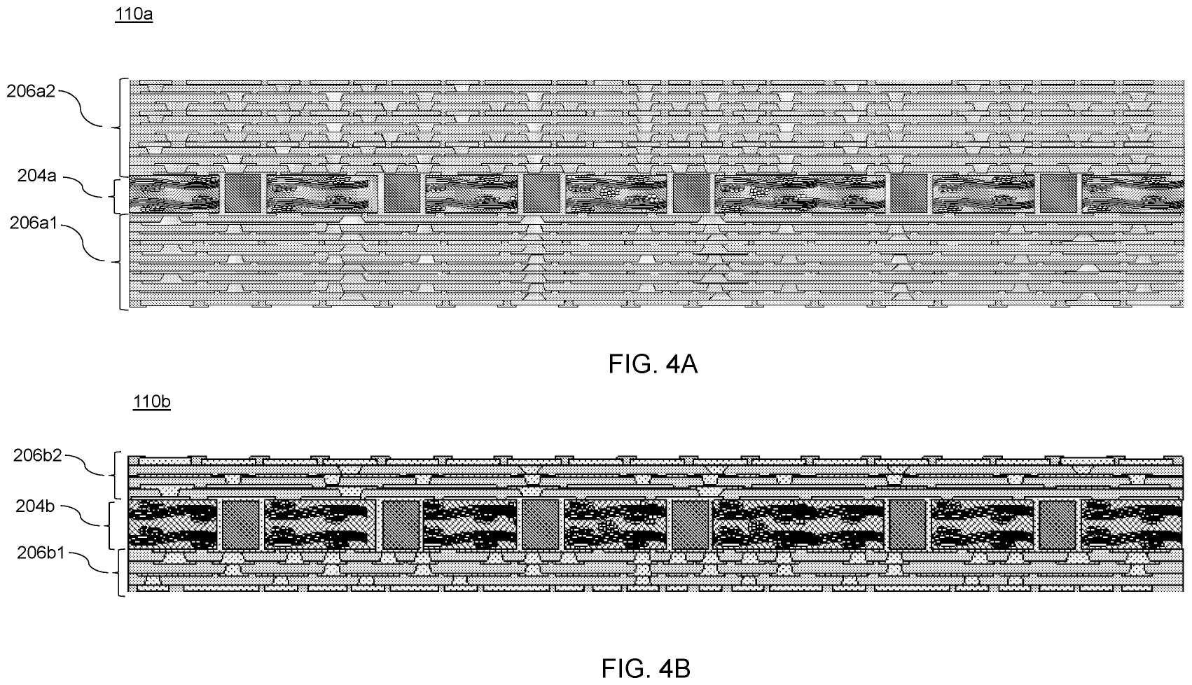

The plurality of first redistribution layers 302a may provide some of the functionality otherwise provided by the silicon first interposer 108a of the semiconductor package 200 of FIG. 2, while the plurality of second redistribution layers 302b may provide some of the functionality otherwise provided by the first package substrate 110a of the semiconductor package 200 of FIG. 2. In this regard, the plurality of first redistribution layers 302a may be configured to provide high-speed die-to-die communication channels between the first semiconductor die 104 and the second semiconductor 106, while the plurality of second redistribution layers 302b may be configured to provide enhanced power delivery channels relative to those of the silicon first interposer 108a of the semiconductor package 200 of FIG. 2. The plurality of second redistribution layers 302b may be further configured such that the plurality of metal bumps 124 may have a relaxed (i.e., larger) pitch relative to a pitch of the corresponding metal bumps 124 of the semiconductor package 200 of FIG. 2. As such, the second package substrate 110b of the semiconductor package 300 of FIG. 3 may have a simpler structure (e.g., have fewer interconnect layers) than that of the first package substrate 110a of the semiconductor package 200 of FIG. 2, as described in greater detail with reference to FIGS. 4A and 4B, below.

The first electrical interconnect structures 304a of the plurality of first redistribution layers 302a may be embedded in a first dielectric material 306a, and the second electrical interconnect structures 304b of the plurality of second redistribution layers 302b may be embedded in a second dielectric material 306b. According to various embodiments, the first dielectric material 306a may include a first polymer and the second dielectric material may include an inorganic particulate material dispersed in a second polymer. The first polymer may include one of polyimide (PI), benzocyclobutene (BCB), polybenzo-bisoxazole (PBO), or any polymer material having similar properties. The second polymer may include a polymer resin (e.g., epoxy, cyanate esters, etc.) and the inorganic particulate material may include a silica powder or other similar particulate material. Each of the first dielectric material 306a and the second dielectric material 306b may be configured to allow the formation of redistribution layer vias and traces using a process in which the dielectric materials (306a, 306b) may be lithographically patterned, etched (and/or laser drilled), and electroplated to form conductive traces and vias. The first dielectric material 306a may be configured to allow fine features to be formed and the second dielectric material 306b may be configured to allow larger features to be formed.

The first dielectric material 306a may be configured to have greater elasticity than that of the second dielectric material 306b. As such, second dielectric material 306b may be a stronger material (e.g., having greater modulus) which may act to strengthen a central region of the second interposer 108b similar to the way in which the core structure 204a of the first package substrate 110a of FIG. 2 may strengthen the first package substrate 110a. Conversely, the first dielectric material 306a of the plurality of first redistribution layers 302a may allow a relatively greater elastic deformation which may act to reduce thermal stresses/strains at an interface between the second interposer 108b and other components of the semiconductor package 300 including the first semiconductor die 104, the second semiconductor die 106, the first underfill material portion 122, and the EMC frame 202.

As shown in FIG. 3, the first electrical interconnect structures 304a may be electrically connected to the second electrical interconnect structures 304b such that the second interposer 108b has a slab geometry having a first surface 308a and a second surface 308b that is parallel to the first surface 308a. The first surface 308a may include electrical micro-bump structures (e.g., metal bumps 120) that may be electrically connected to the first electrical interconnect structures 304a of the of the plurality of first redistribution layers 302a. Similarly, second surface 308b may include electrical bonding pad structures 310 electrically connected to the second electrical interconnect structures 304b of the plurality of second redistribution layers 302b. The second interposer 108b may further include a protective layer 312 formed over the first surface 308a such that the protective layer 312 is formed over the plurality of first redistribution layers 302a and partially surrounds the electrical micro-bump structures 120. The protective layer 312 may be formed of the second dielectric material 306b to thereby strengthen the interface between the second interposer 108b and other components of the semiconductor package 300 including the first semiconductor die 104, the second semiconductor die 106, the first underfill material portion 122, and the EMC frame 202.

The plurality of second redistribution layers 302b may further include a surface layer 314 formed proximate to the second surface 308b of the second interposer 108b such that the surface layer 314 may partially surround the electrical bonding pad structures 310. The surface layer 314 may be formed of the first dielectric material 306a which, as described above, may have greater elasticity than the second dielectric material 306b. As such, the surface layer 314 may allow a greater degree of elastic deformation than that of the second dielectric material 306b. Such elastic deformation may thereby reduce thermally induced stresses/strains that may otherwise develop between the second interposer 108b and the second package substrate 110b.

FIG. 4A is a vertical cross-sectional view of the first package substrate 110a of the semiconductor package 200 of FIG. 2 and FIG. 4B is a vertical cross-sectional view a second package substrate 110b that may be used in the semiconductor package 300 of FIG. 3, according to various embodiments. As described above, the second package substrate 110b of the semiconductor package 300 of FIG. 3 may have a simpler structure than that of the semiconductor package 200 of FIG. 2. In this regard, as described above with reference to FIG. 3, the second interposer 108b of FIG. 3 may provide some of the functionality otherwise provided by the first package substrate 110a due to the presence of the plurality of second redistribution layers 302b. In this way, some of the second redistribution layers 302b of the second interposer 108b may eliminate the need for some of the electrical interconnects of the first package substrate 110a, thus allowing the second package substrate 110b to have fewer electrical interconnect layers.

Each of the first package substrate 110a and the second package substrate 110b may include respective core structures (204a, 204b) which may each have a similar structure (e.g., two or more electrical interconnect layers). Similarly, each of the first package substrate 110a and the second package substrate 110b may include a respective first interconnect structure (206a1, 206b1) formed below the respective core structure (204a, 204b) and a respective second interconnect structure (206a2, 206b2) formed above the respective core structure (204a, 204b). As shown in FIG. 4B, however, the first interconnect structure 206b1 and the second interconnect structure 206b2 of the second package substrate 110b may include fewer electrical interconnect layers than the corresponding first interconnect structure 206al and second interconnect structure 206a2 of the first package substrate 110a.

For example, while the first interconnect structure 206al and second interconnect structure 206a2 of the first package substrate 110a may each include nine interconnect layers, the corresponding first interconnect structure 206b1 and second interconnect structure 206b2 of the second package substrate 110b may each include three interconnect layers. Various other numbers of interconnect layers may be formed in the first package substrate 110a and the second package substrate 110b in other embodiments, but in general, the second package substrate 110b may have fewer interconnect layers than that of the first package substrate 110a when used in conjunction with the second interposer 108b. A semiconductor package such as the semiconductor package 300 that includes a simplified package substrate, such as the second package substrate 110b, may exhibit reduced thermal-induced deformation, warpage, cracking, delamination, etc., and thus may represent a further improvement of the semiconductor package 300 of FIG. 3 relative to the semiconductor package 200 of FIG. 2.

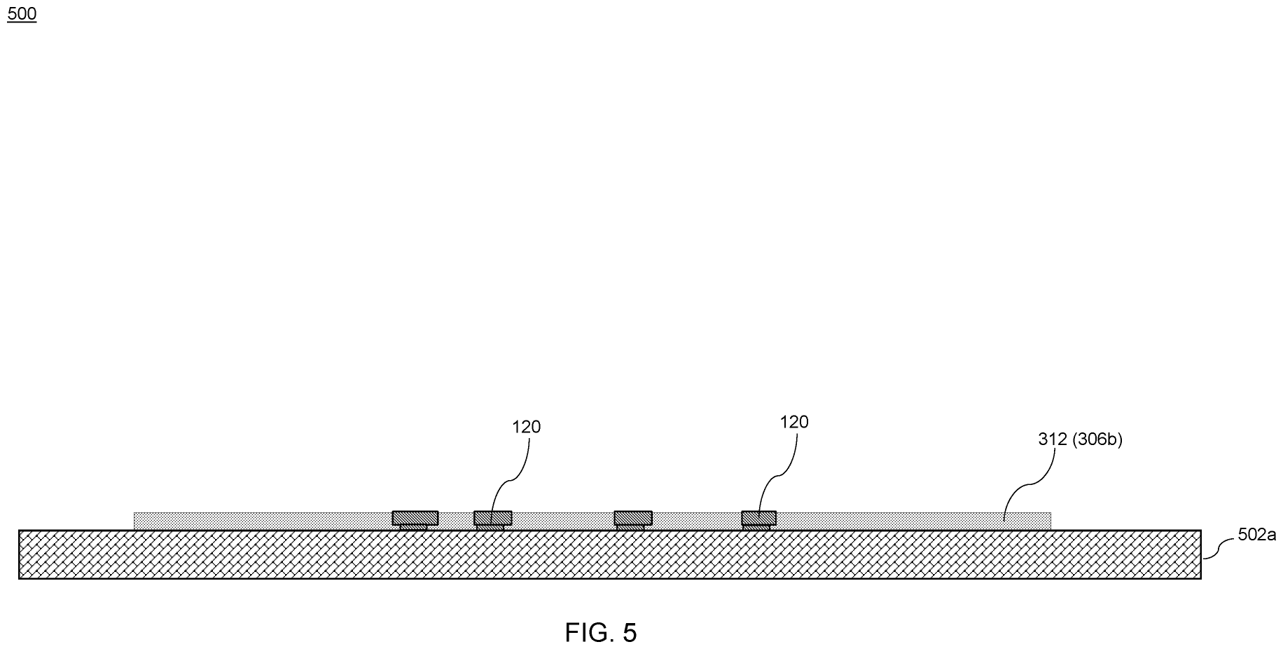

FIG. 5 is a vertical cross-sectional view of an intermediate structure 500 that may be used to form a semiconductor package 300, according to various embodiments. In a first operation, the protective layer 312 may be formed over a first carrier substrate 502a. In this regard, a layer of the second dielectric material 306b may be removably attached to the first carrier substrate 502a using an adhesive (not shown). The adhesive may be chosen to have a material composition that allows de-activation by application of heat or ultraviolet radiation so that the adhesive may be de-activated, so that the first carrier substrate 502a may be removed, in a subsequent processing operation.

As described above, the second dielectric material 306b may include an inorganic particulate reinforcing phase formed in a polymer resin material. The second dielectric material 306b may be provided as a film containing one or more resins (e.g., epoxy, cyanate esters), hardeners, and fillers in an uncured state. The film may be adhered to the first carrier substrate 502a using the adhesive described above. The film may then be cured by subjecting the film to an annealing process wherein the film is subjected to an elevated temperature for a certain period of time. For example, the film by be held at a temperature of between 100° C. and 200° C. for 15 minutes to 60 minutes. For example, a first annealing process may be performed at 100° C. for 30 minutes followed by a second annealing process at 200° C. for 30 minutes. The one or more annealing processes may act to cause cross-linking to thereby cure the second polymer (i.e., of the second dielectric material 306b) to thereby form the protective layer 312.

The protective layer 312 may then be patterned to form via holes (not shown) that may subsequently be filled with a conductive material to form the electrical micro-bump structures 120, described above. In an example embodiment, a process of laser drilling may be performed to generate via holes (not shown) in the protective layer 312. The laser drilling process may remove portions of the protective layer 312 such that the holes may extend through the protective layer. The electrical micro-bump structures 120 may then be formed by filling the via holes with a conductive material, such as copper, using a deposition process such as electroplating. Other suitable conductive materials and deposition processes are within the contemplated scope of disclosure. In various embodiments, a seed layer (e.g., a Ti/Cu layer) may be deposited (e.g., by sputtering) before the conductive material is deposited.

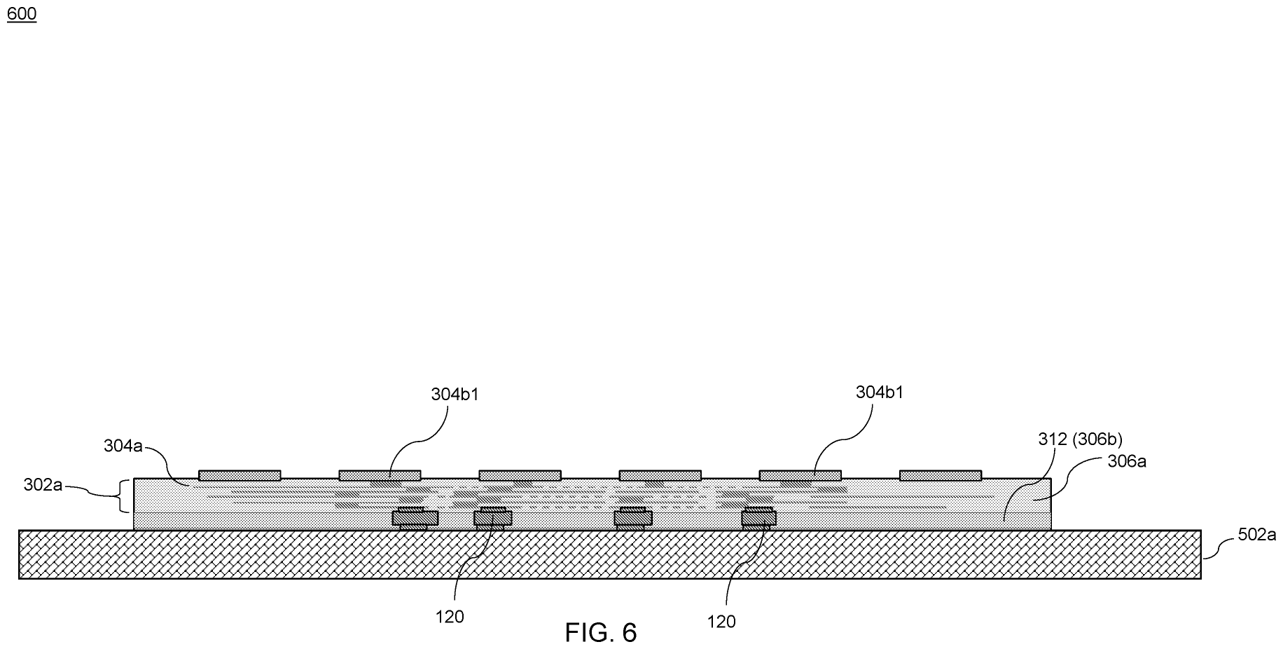

FIG. 6 is a vertical cross-sectional view of a further intermediate structure 600 that may be used to form a semiconductor package 300, according to various embodiments. The intermediate structure 600 may be formed from the intermediate structure 500 of FIG. 5 by forming the plurality of first redistribution layers 302a over the protective layer 312. Each of the plurality of first redistribution layers 302a may be formed by performing a plurality of operations. In a first operation, a layer of the of the first dielectric material 306a may be formed over the protective layer 312 in forming an initial layer, or over previous layers, in forming subsequent layers of the plurality of first redistribution layers 302a. As described above, the first dielectric material 306a may include a first polymer that may include PI, BCB, PBO, or any polymer material having similar properties. A spin-coating process may be performed to generate a layer of the first polymer. In various embodiments, the layer of the first polymer may have a thickness of between 4 microns to 7 microns.

In a further operation, a patterned photoresist (not shown) may be formed over the layer of the first polymer. The patterned photoresist may be formed by forming a blanket layer of a photoresist material followed by patterning the photoresist using lithographic techniques. In a further operation, patterned photoresist may be used to etch the first polymer to form a patterned first polymer layer including features (e.g., via holes) that may be subsequently filled with a conducting material to form the portions of first electrical interconnect structures 304a. In a further operation, the patterned photoresist may be removed (e.g., by dissolution with a solvent or by dry film stripping) and a seed layer (e.g., a Ti/Cu seed layer) may be formed (e.g., by sputtering) over the patterned first polymer layer.

In a further operation, a further patterned photoresist (e.g., including features corresponding to line traces) may be formed and the first electrical interconnect structures 304a may be formed by depositing (e.g., by electroplating) a conducting material (e.g., Cu, Ni, etc.) over the patterned photoresist and first polymer layer. In a further operation, the patterned photoresist may be removed (e.g., by dissolution with a solvent or by dry film stripping) and the seed layer may be removed (e.g., by etching). The above operations may be repeated a plurality of times to generate the corresponding additional first redistribution layers 302a. As shown in FIG. 6, when generating the top layer of the plurality of first redistribution layers 302a, larger conducting features (e.g., electrically conductive lines 304b1) may be formed that may serve as a first layer of the plurality of second electrical interconnect structures 304b of the second redistribution layers 302b.

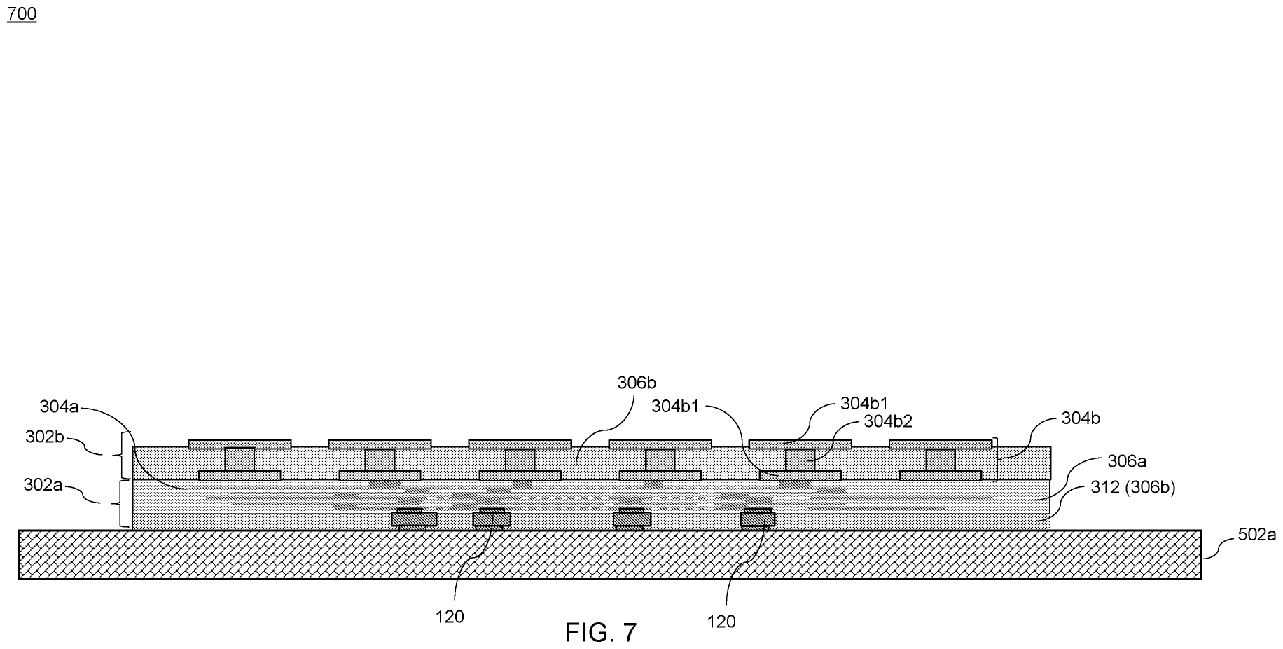

FIG. 7 is a vertical cross-sectional view of a further intermediate structure 700 that may be used to form a semiconductor package 300, according to various embodiments. The intermediate structure 700 may be formed from the intermediate structure 600 of FIG. 6 by forming a first one of the plurality of second redistribution layers 302b over the plurality of first redistribution layers 302a. In this regard, a layer of the second dielectric material 306b may be formed over the plurality of first redistribution layers 302a. As described above with reference to FIG. 6, a top layer of the plurality of first redistribution layers 302a may include electrically conductive lines 304b1 that may form a lowest level of the second electrical interconnect structures 304b. As shown, the second electrical interconnect structures 304b may include electrically conductive lines 304b1 and electrically conductive vias 304b2.

Each of the plurality of second redistribution layers 302b may be formed by performing a plurality of operations. In a first operation, a layer of the second dielectric material 306b may be formed over the top layer of the plurality of first redistribution layers 302a in forming an initial layer, or over or over previous layers, in forming subsequent layers of the plurality of second redistribution layers 302b. As described above with reference to FIG. 5, the second dielectric material 306b may include an inorganic particulate reinforcing phase formed in a polymer resin material. The second dielectric material 306b may be provided as a film containing one or more resins (e.g., epoxy, cyanate esters), hardeners, and fillers in an uncured state. The film may be placed over a previous layer (e.g., the top layer of the plurality of first redistribution layers 302a in forming an initial layer, or over previously formed layers, of the plurality of second redistribution layers 302b) and may be subjected to a first annealing process. For example, a first annealing process may be conducted at, for example, 100° C. for 30 minutes. The first annealing process may soften the second dielectric material 306b without curing/cross-linking the second dielectric material 306b thus allowing the second dielectric material 306b to conform to underlying structures (e.g., the electrically conductive lines 304b1 of an underlying layer). A second annealing process may then be conducted, for example, at 200° C. for 30 minutes to thereby cure/cross-link the second dielectric material 306b.

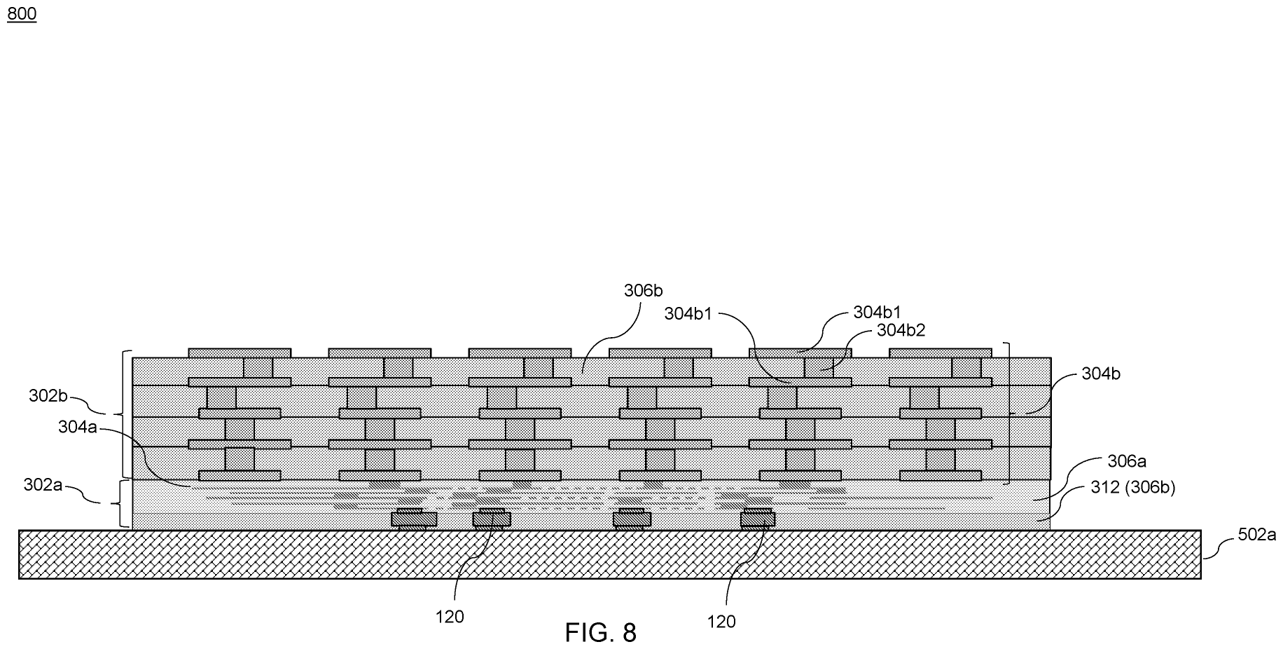

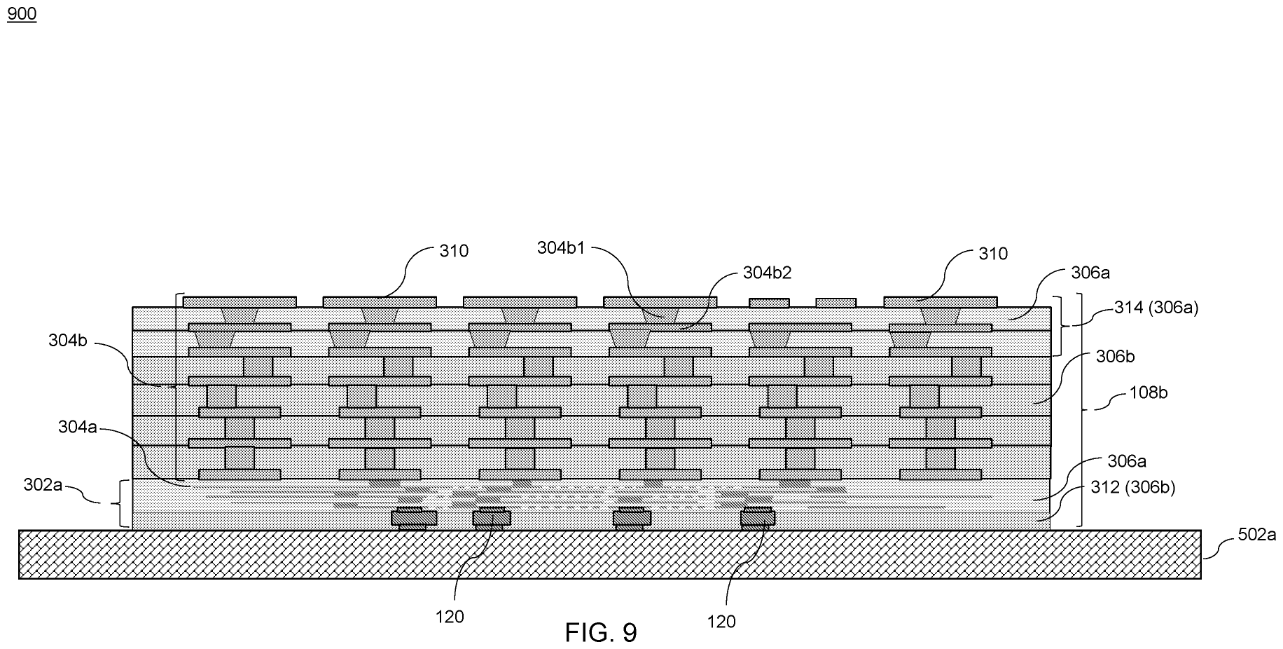

In a further operation, a laser drilling operation may be performed to generate via holes (not shown) which may subsequently be filled with a conductive material to form the electrically conductive vias 304b2. In a further operation, a seed layer (e.g., a Ti/Cu seed layer) may be formed over the second dielectric material 306b and within the via holes. In a further operation, a patterned photoresist may be formed over the seed layer. The patterned photoresist may be formed by forming a blanket layer of photoresist and patterning the photoresist with lithographic techniques. The patterned photoresist may be used to define line structures that may be subsequently filled with a conductive material (e.g., Ni, Cu, etc.) to form the electrically conductive lines 304b1. Openings of the patterned photoresist may be located over previously formed via holes such that, upon deposition of a conductive material, the electrically conductive lines 304b1 and the electrically conductive vias 304b2 may be formed in a single operation and may be electrically connected to one another. In a further operation, the conductive material (e.g., Ni, Cu, etc.) may be deposited (e.g., by electroplating) to thereby fill patterned portions of the patterned photoresist to thereby form the electrically conductive lines 304b1 and the electrically conductive vias 304b2. In a further operation, the patterned photoresist may be removed (e.g., by dissolution with a solvent or by dry film stripping) and the seed layer may be removed (e.g., by etching). The above operations may be repeated a plurality of times to generate the corresponding additional layers of the plurality of second redistribution layers 302b as shown, for example, in FIGS. 8 and 9.

FIG. 8 is a vertical cross-sectional view of a further intermediate structure 800 that may be used to form a semiconductor package 300, according to various embodiments. The intermediate structure 800 may be formed from the intermediate structure 700 of FIG. 7 by repeating the operations described above with reference to FIG. 7 to generate additional layers of the plurality of second redistribution layers 302b. In this example, FIG. 8 shows an intermediate structure 800 that includes three additional layers of the plurality of second redistribution layers 302b that are formed over the first layer of the plurality of second redistribution layers 302b of FIG. 7 for a total of four layers. In various embodiments, additional layers of the plurality of second redistribution layers 302b may be formed over the intermediate structure 800 of FIG. 8. Alternatively, or in addition to the formation of additional layers, a surface layer 314 (e.g., see FIG. 3) may be formed over the intermediate structure 800 of FIG. 8, as described in greater detail with reference to FIG. 9, below.

FIG. 9 is a vertical cross-sectional view of a further intermediate structure 900 that may be used to form a semiconductor package 300, according to various embodiments. The intermediate structure 900 may be formed from the intermediate structure 800 of FIG. 8 by forming the surface layer 314 using techniques similar to those described above with reference to FIG. 6. In this regard, two additional layers of the plurality of second redistribution layers 302b may be embedded within the first dielectric material 306a. As described above with reference to FIG. 3, the use of the first dielectric material 306a may allow the surface layer 314 to have a greater degree of elasticity relative to the harder second dielectric material 306b. Operations similar to those used to form the plurality of first redistribution layers 302a may be used to form the surface layer 314. For example, a first polymer (e.g., PI, BCB, PBO, etc.) may be formed by a spin coating process. A patterned photoresist may then be formed over the first polymer layer and the patterned photoresist may be used to etch the first polymer to form via holes (not shown). The patterned photoresist may then be removed and a seed layer may be formed.

In a further operation, a further patterned photoresist (e.g., including features corresponding to line traces) may be formed and additional second electrical interconnect structures 304b may be formed by depositing (e.g., by electroplating) a conducting material (e.g., Cu, Ni, etc.) over the patterned photoresist and first polymer layer. In a further operation, the patterned photoresist may be removed (e.g., by dissolution with a solvent or by dry film stripping) and the seed layer may be removed (e.g., by etching). The above operations may be repeated a plurality of times to generate the corresponding additional layers of the surface layer 314. In this example embodiment, the surface layer 314 is shown with two layers of second electrical interconnect structures 304b but various numbers of additional layers of second electrical interconnect structures 304b may be provided in other embodiments. Also, as shown in FIG. 9, in the final layer of the surface layer 314 electrical bonding pad structures 310 may be formed and may be electrically connected to the second electrical interconnect structures 304b of the plurality of second redistribution layers 302b. The electrical bonding pad structures 310 may be formed by filling (e.g., by electroplating) corresponding features in a patterned photoresist by performing operations similar to those described above.

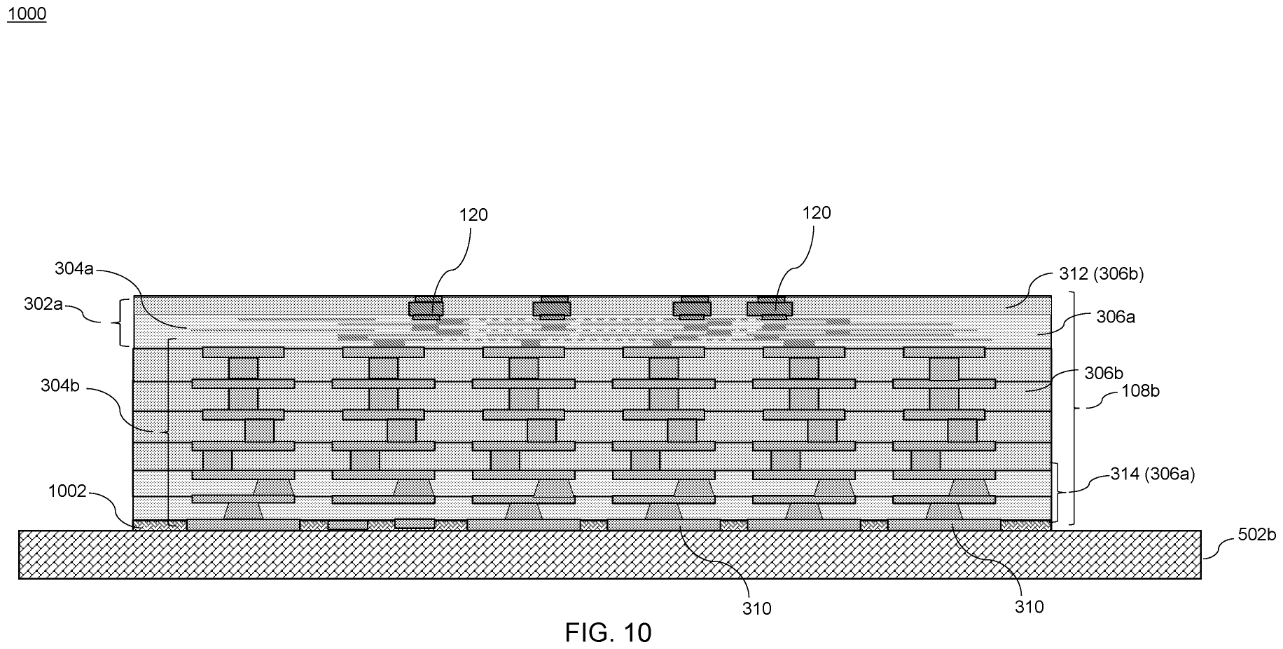

FIG. 10 is a vertical cross-sectional view of a further intermediate structure 1000 that may be used to form a semiconductor package 300, according to various embodiments. The intermediate structure 1000 may be formed from the intermediate structure 900 of FIG. 9 by attaching a second carrier substrate 502b to the surface layer 314 and electrical bonding pad structures 310, removing the first carrier substrate 502a, and inverting the resulting structure. In this regard, the second carrier substrate 502b may be removably attached using an adhesive 1002, which may be chosen to have a material composition that allows de-activation by application of heat or ultraviolet radiation so that the adhesive may be de-activated to allow the second carrier substrate 502b to be removed, in a subsequent processing operation. Similarly, the first carrier substrate 502a may be removed by de-activated the adhesive (not shown) between the first carrier substrate 502a and the protective layer 312 by application of a heat treatment or by application of ultraviolet radiation. Once the adhesive has been de-activated, the first carrier substrate 502a may be removed.

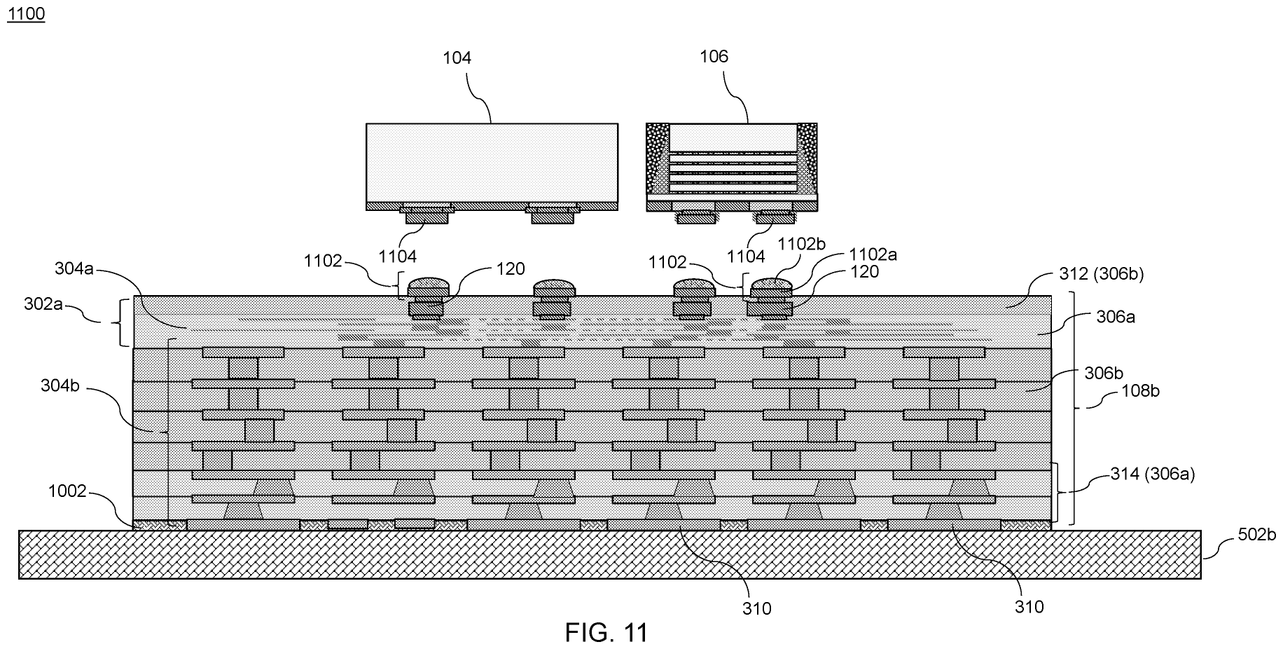

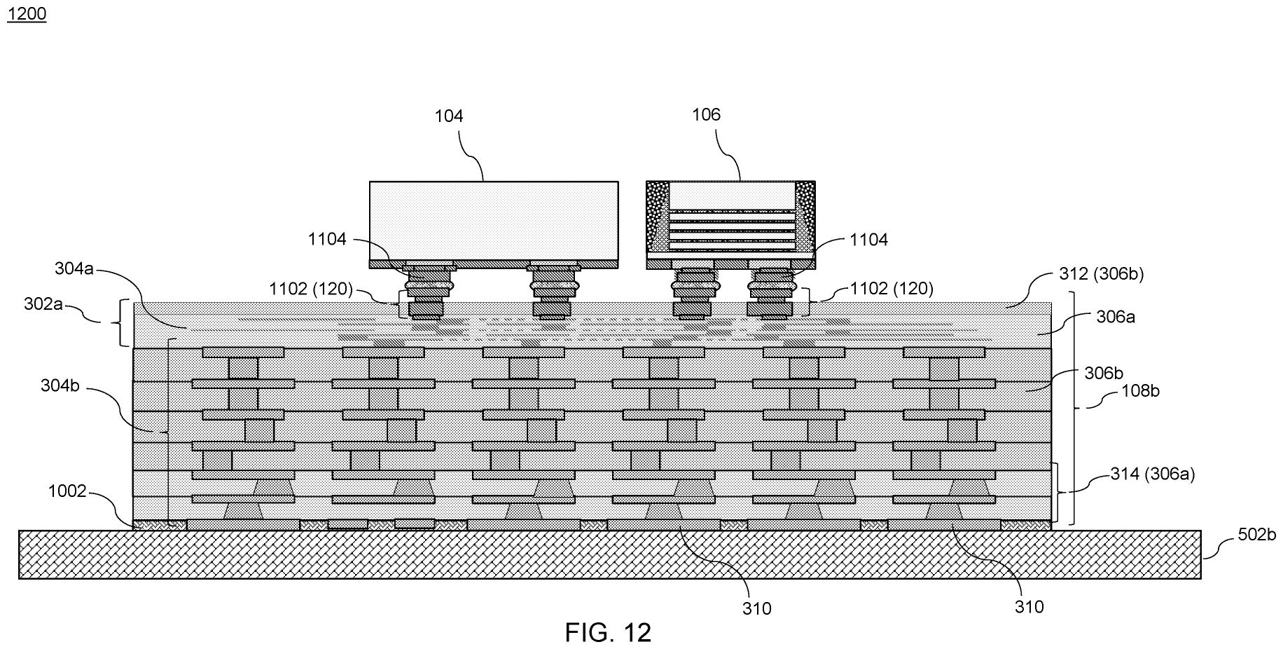

FIG. 11 is a vertical cross-sectional view of a further intermediate structure 1100 that may be used to form a semiconductor package 300, according to various embodiments. The intermediate structure 1100 may be formed from the intermediate structure 1000 of FIG. 10 by forming additional bonding structures 1102 (e.g., C2 bumps 1102) over the electrical micro-bump structures 120. In this regard, the additional bonding structures 1102 may include a micro-pillar 1102a and a solder cap 1102b. As shown, a first semiconductor die 104 and a second semiconductor die 106 may then be positioned relative to the bonding structures 1102 such that that bonding structures 1102 may be aligned with corresponding bonding structures 1104 of the first semiconductor die 104 and the second semiconductor die 106.

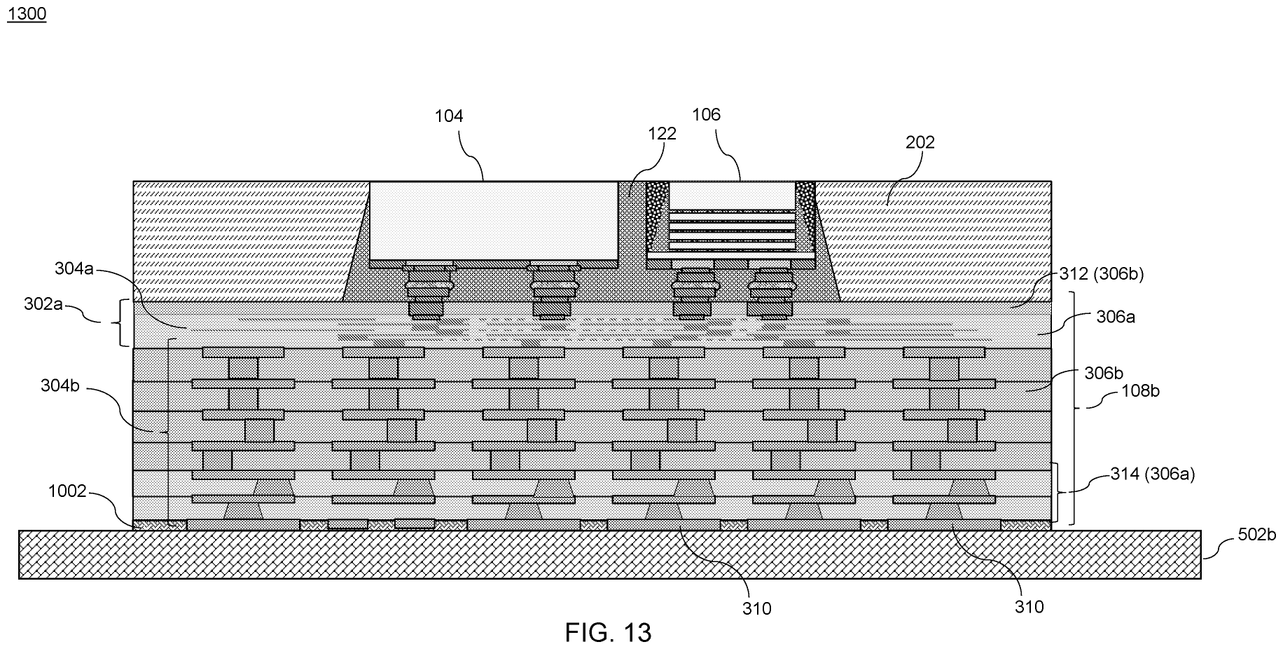

FIG. 12 is a vertical cross-sectional view of a further intermediate structure 1200 that may be used to form a semiconductor package 300, and FIG. 13 is a vertical cross-sectional view of a further intermediate structure 1300 that may be used to form a semiconductor package 300, according to various embodiments. The intermediate structure 1200 of FIG. 12 may be formed from the intermediate structure 1100 of FIG. 11 by bringing the bonding structures 1104 of the first semiconductor die 104 and the second semiconductor die 106 in contact with the corresponding additional bonding structures 1102 of the second interposer 108b and by performing a reflow operation. The reflow operation may cause the solder cap 1102b of the additional bonding structures 1102 to melt and, upon cooling, to form a mechanical and electrical bond between the second interposer 108b and the first semiconductor die 104 and between the second interposer 108b and the second semiconductor die 106.

The intermediate structure 1300 of FIG. 13 may then be formed from the intermediate structure 1200 of FIG. 12 by forming a first underfill material portion 122 provided in the spaces laterally separating the first semiconductor die 104 and second semiconductor die 106 and in spaces between the first semiconductor die 104 and the second interposer 108b and in spaces between the second semiconductor die 106 and the second interposer 108b. A multi-die EMC frame 202 may then be formed such as to partially surround the first semiconductor die 104 and the second semiconductor die 106, as described in greater detail, above.

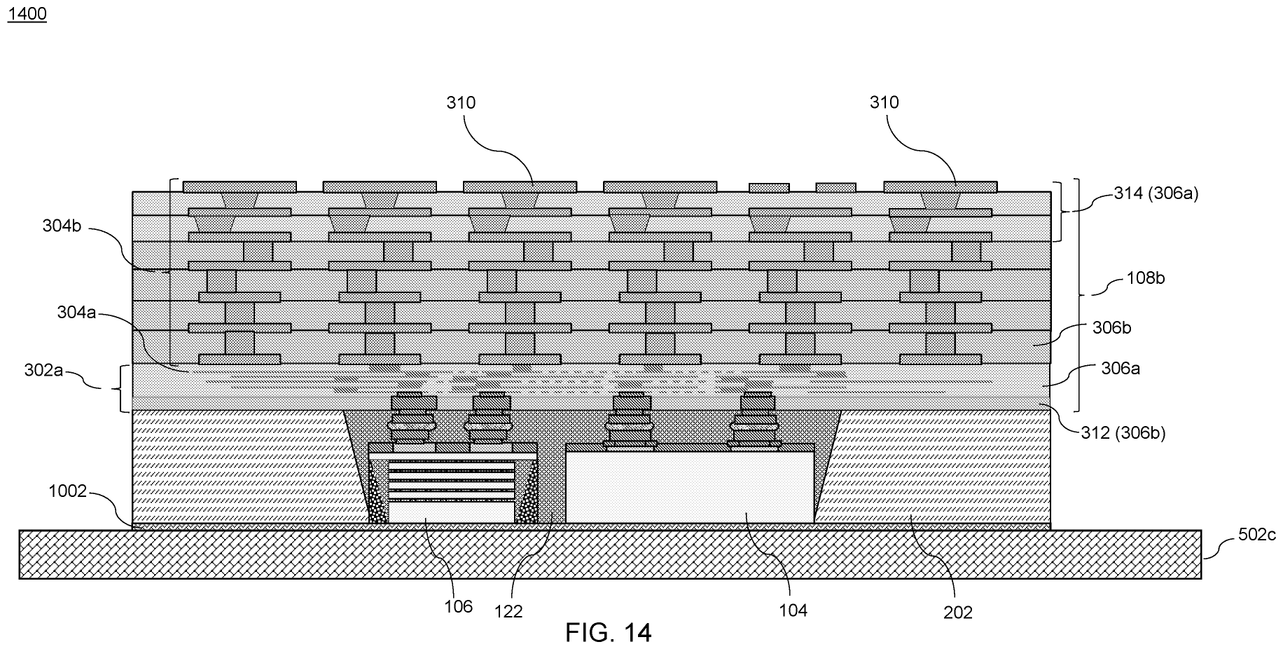

FIG. 14 is a vertical cross-sectional view of a further intermediate structure 1400 that may be used to form a semiconductor package 300, according to various embodiments. The intermediate structure 1400 may be formed from the intermediate structure 1300 of FIG. 13 by attaching a third carrier substrate 502c to a top surface of the intermediate structure 1300 (e.g., including top surfaces of the first semiconductor die 104 and the second semiconductor die 106), removing the second carrier substrate 502b, and inverting the resulting structure. In this regard, the third carrier substrate 502c may be removably attached using an adhesive 1002, which may be chosen to have a material composition that allows de-activation by application of heat or ultraviolet radiation so that the adhesive may be de-activated to allow third carrier substrate 502c may be removed, in a subsequent processing operation. Similarly, the second carrier substrate 502b may be removed by de-activated the adhesive 1002 between the second carrier substrate 502b and the surface layer 314 by application of a heat treatment or by application of ultraviolet radiation. Once the adhesive has been de-activated, the second carrier substrate 502b may be removed.

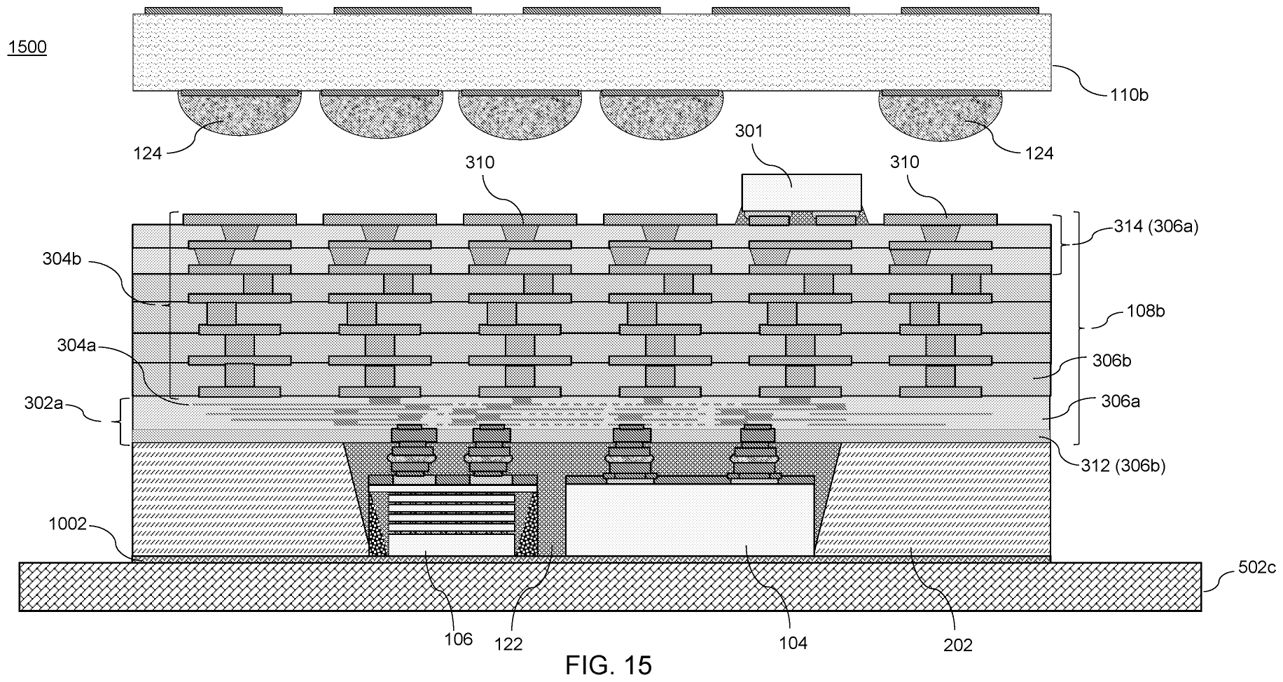

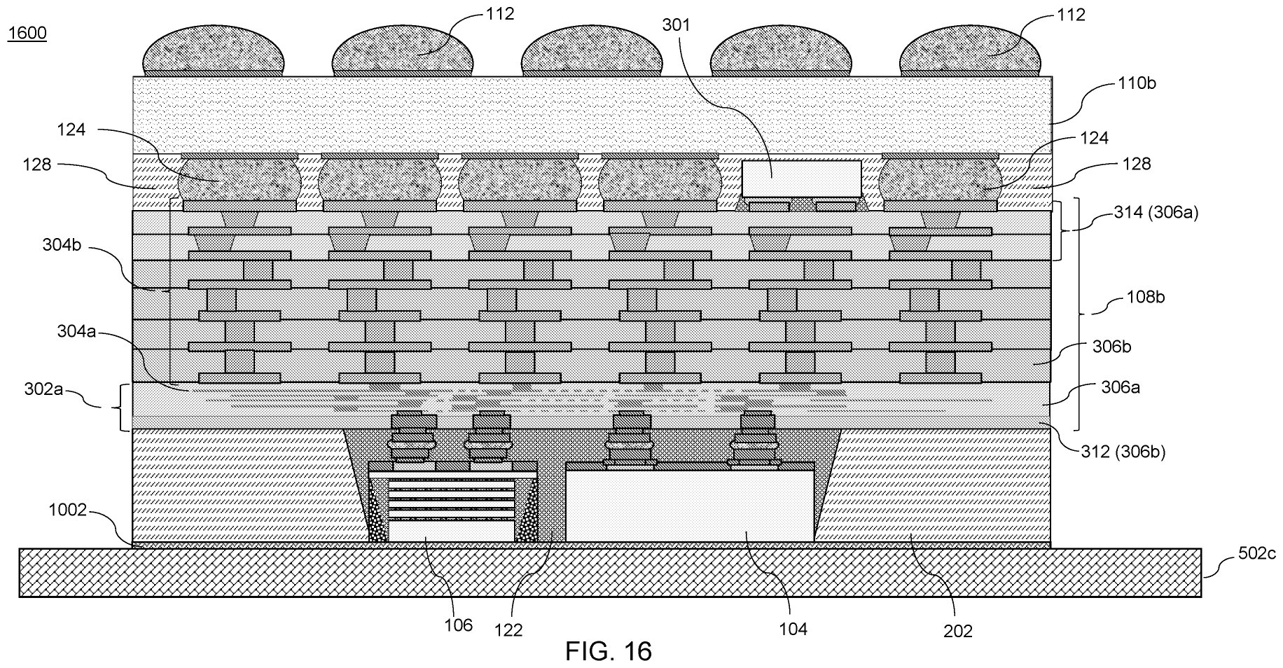

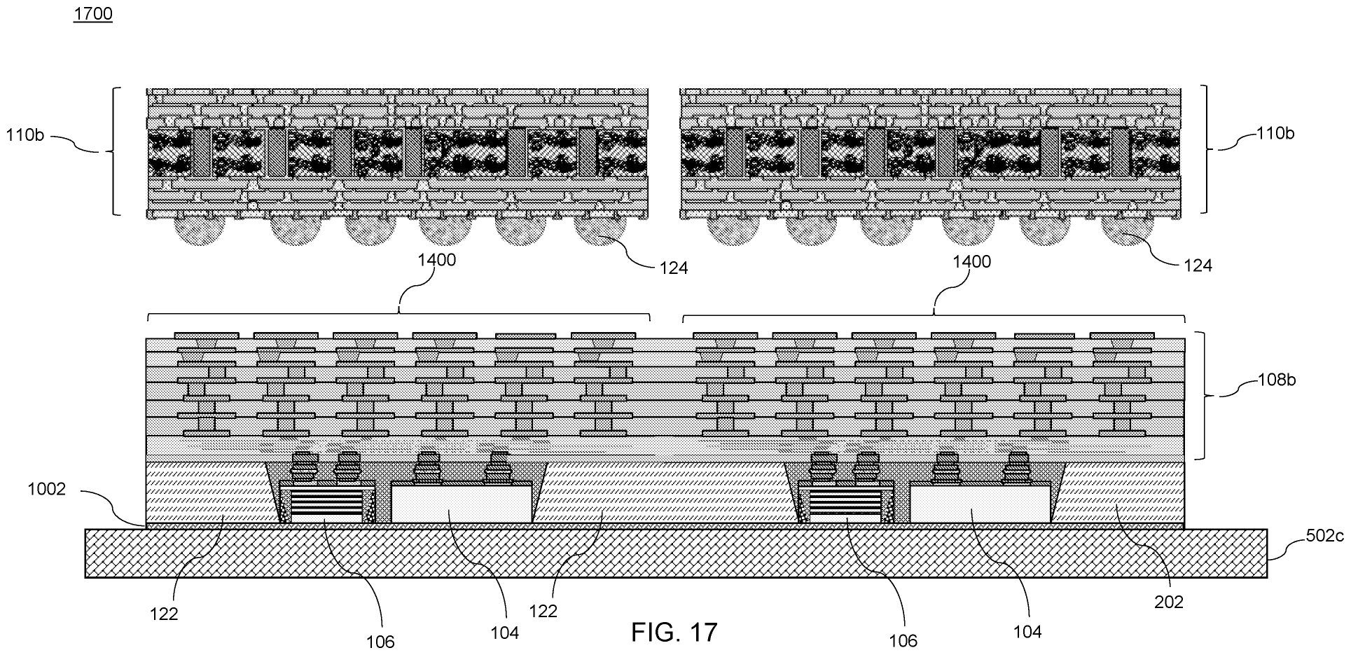

FIG. 15 is a vertical cross-sectional view of a further intermediate structure 1500 that may be used to form a semiconductor package 300, and FIG. 16 is a vertical cross-sectional view of a further intermediate structure 1600 that may be used to form a semiconductor package 300, according to various embodiments. The intermediate structure 1500 may be formed from the intermediate structure 1400 of FIG. 14 by attaching an integrated passive device 301 to the second interposer 108b, and the intermediate structure 1600 may be formed from the intermediate structure 1500 of FIG. 15 by attaching the second package substrate 110b to the intermediate structure 1500 of FIG. 15. The semiconductor package 300 may then be formed from the intermediate structure 1600 by removing the third carrier substrate 502c. In this regard, the third carrier substrate 502c be removed by de-activated the adhesive 1002) by application of a heat treatment or by application of ultraviolet radiation. Once the adhesive has been de-activated, the third carrier substrate 502c may be removed. In various embodiments, the second package substrate 110b may have the simplified structure described above with reference to FIG. 4B, as described in greater detail with reference to FIGS. 17 to 19B, below.

FIG. 17 is a vertical cross-sectional view of a further intermediate structure 1700 that may be used to form a semiconductor package 300. As shown in FIG. 17, for example, a plurality of intermediate structures 1400 (see FIG. 14 and related description, above) may be formed over a third carrier substrate 502c using methods described with reference to FIGS. 5 to 1400 above. Similarly, a plurality of second package substrates 110b may be separately formed and positioned above the respective plurality of intermediate structures 1400.

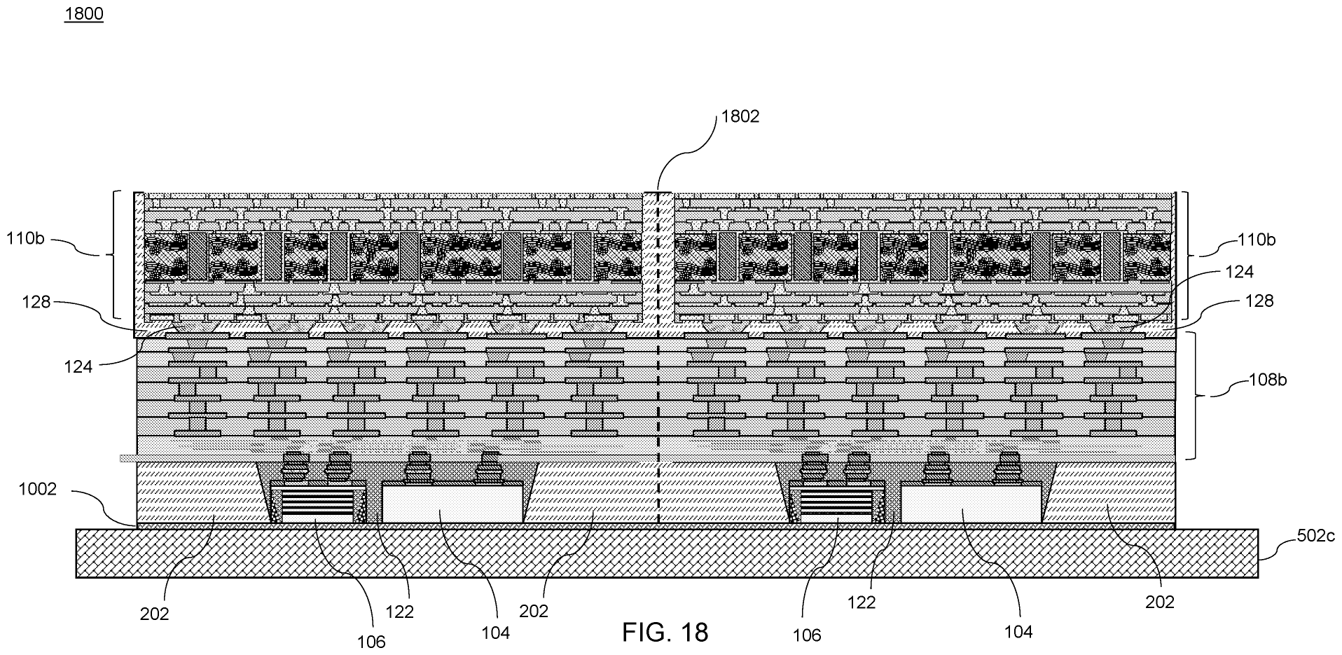

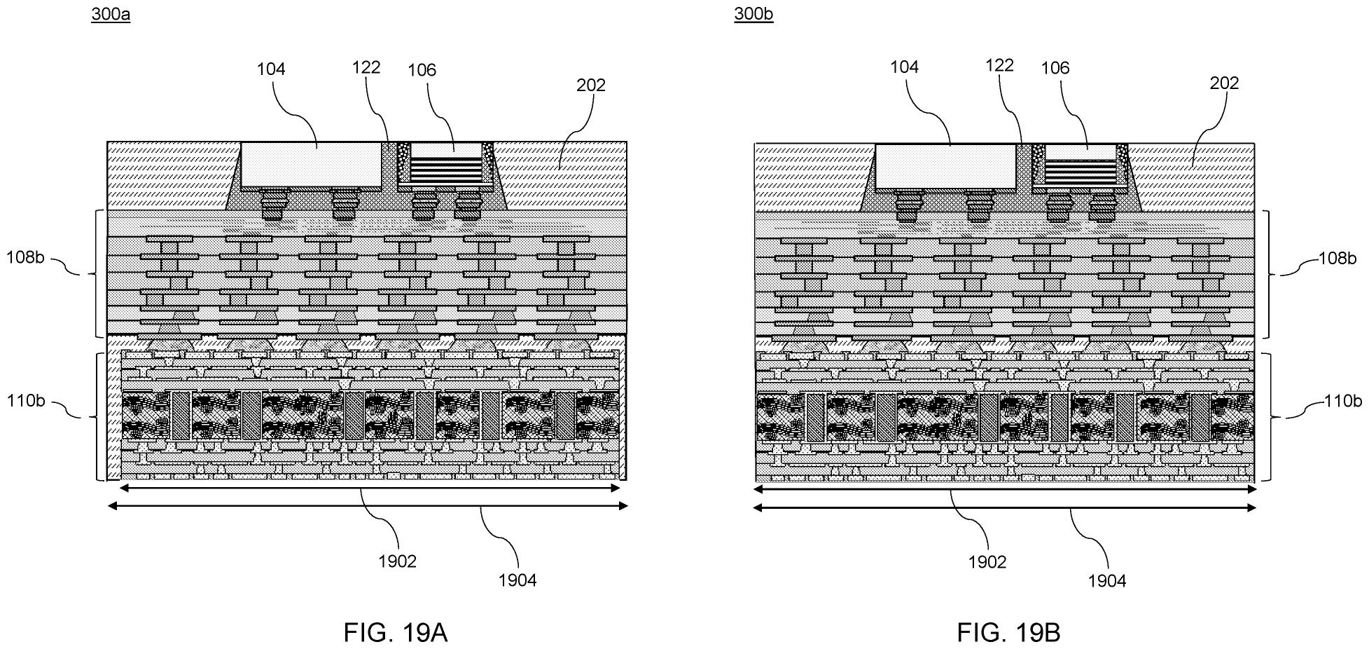

FIG. 18 is a vertical cross-sectional view of a further intermediate structure 1800 that may be used to form a semiconductor package 300, according to various embodiments. As shown in FIG. 18, the intermediate structure 1800 may be formed from the intermediate structure 1700 of FIG. 17 by attaching the plurality of second package substrates 100b to the respective intermediate structures 1400, as shown in FIG. 18. In this regard, the second interposer 108b may be electrically and mechanically connected to the second package substrate 110b with a plurality of metal bumps 124 (e.g., C4 solder bumps) by performing a reflow operation to reflow the metal bumps 124 to form the electrical and mechanical connections. A second underfill material portion 128 may be provided in the spaces surrounding the metal bumps 124 and between the bottom surface of the second interposer 108b and an upper surface of the second package substrate 110b. A dicing frame (not shown) may then be attached to the intermediate structure 1800 and the third carrier substrate 502c may be removed. The intermediate structure 1800 may then be singulated/diced along scribe lines/dicing channels 1802 to generate further semiconductor packages (300a, 300b), as described in greater detail with reference to FIGS. 19A and 19b, below.

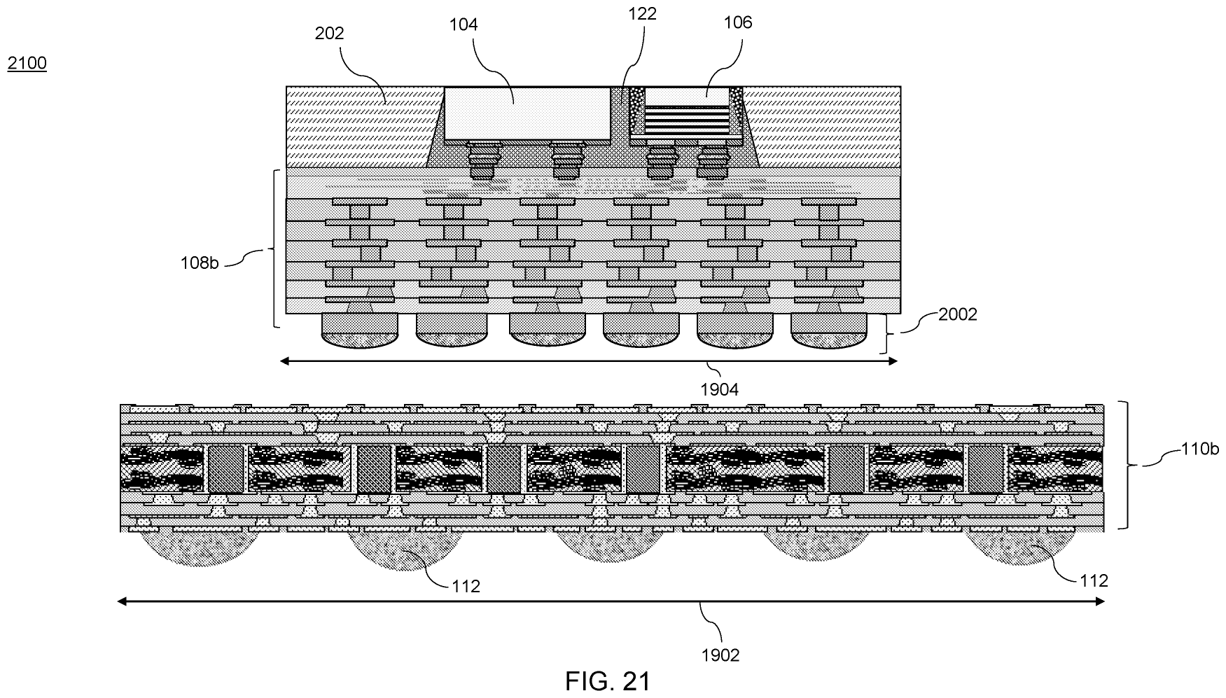

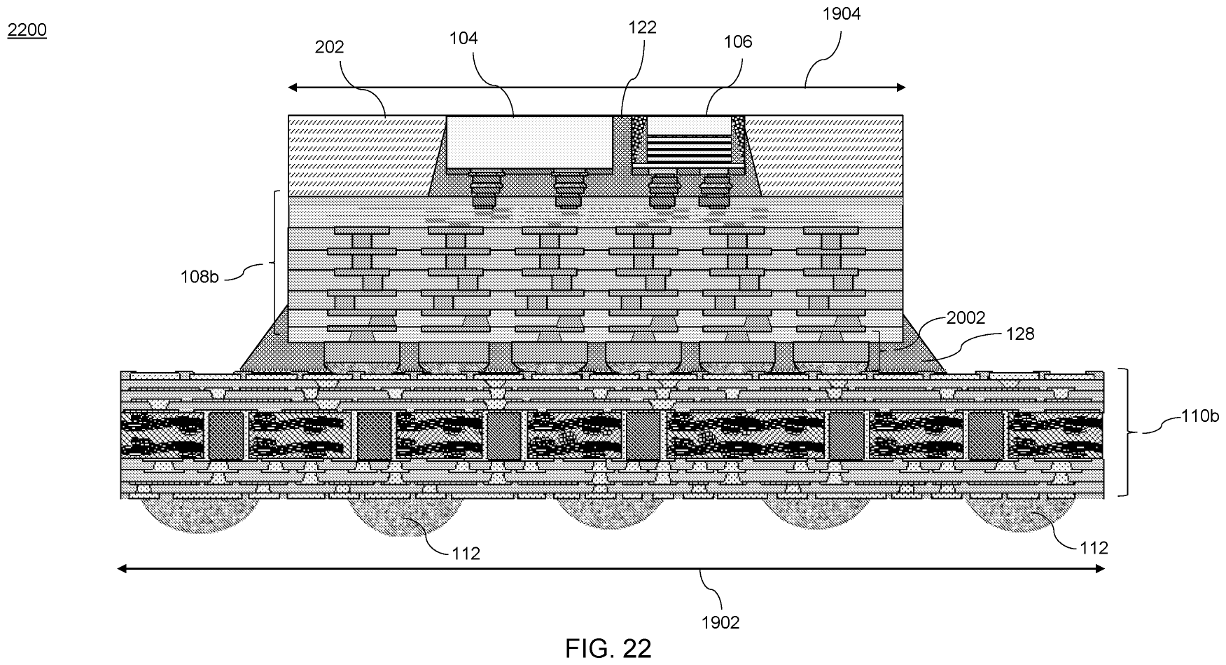

FIG. 19A is a vertical cross-sectional view of an embodiment semiconductor package 300a, and FIG. 19B is a vertical cross-sectional view of a further embodiment semiconductor package 300b, each formed by dicing the intermediate structure 1800, according to various embodiments. As shown in FIG. 19A, the second package substrate 110b may have a width 1902 that may be smaller than a width 1904 of the second interposer 108b after dicing the intermediate structure 1800. Alternatively, after dicing, the second embodiment semiconductor package 300b may be further trimmed such that the width 1902 of the second package substrate 110b is approximately equal to the width 1904 of the second interposer 108b. In other embodiments, a semiconductor package 300c may be formed in which the width 1902 of the second package substrate 110b is greater than the width 1904 of the second interposer 108b, as described in greater detail with reference to FIGS. 21 and 22, below.

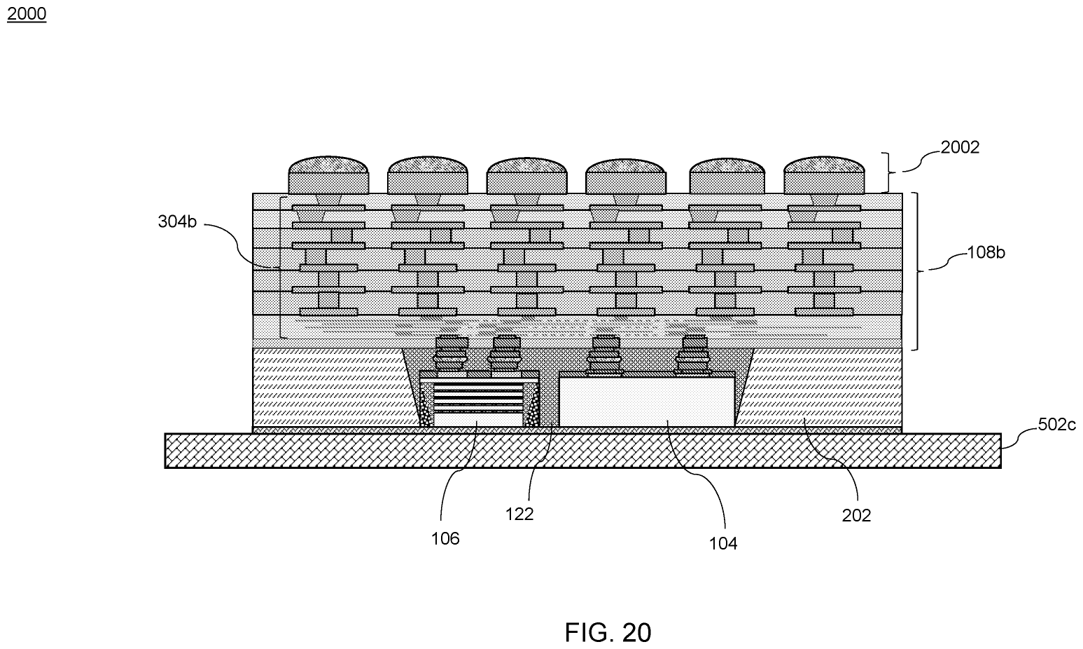

FIG. 20 is a vertical cross-sectional view of a further intermediate structure 2000 that may be used to form a semiconductor package 300c, and FIG. 21 is a vertical cross-sectional view of a further intermediate structure 2100 that may be used to form the semiconductor package 300c, according to various embodiments. FIG. 22 is a vertical cross-sectional view of the semiconductor package 300c that may be formed from the intermediate structures 2100 and 2200 of FIGS. 21 and 22, respectively. The intermediate structure 2000 may be formed from the intermediate structure 1400 of FIG. 14 by forming additional bonding structures 2002 (e.g., C4 bumps) over the intermediate structure 1400 such that the additional bonding structures 2002 are mechanically and electrically connected to the second electrical interconnect structures 304b.

The intermediate structure 2100 of FIG. 21 may then be formed by removing the third carrier substrate 502c from the intermediate structure 2000 and positioning the resulting structure over a separately-formed second package substrate 110b. As shown in FIG. 21, the width 1902 of the second package substrate 110b may be greater than the width 1904 of the second interposer 108b. The semiconductor package 300c may then be formed from the intermediate structure 2100 by attaching the second interposer 108b to the second package substrate 110b by performing a reflow operation to form an electrical and mechanical connection between the additional bonding structures 2002 of the second interposer 108b and the second package substrate 110b. A second underfill material portion 128 may then be provided in the spaces surrounding the additional bonding structures 2002 and between a bottom surface of the second interposer 108b and an upper surface of the second package substrate 110b, as shown in FIG. 22.

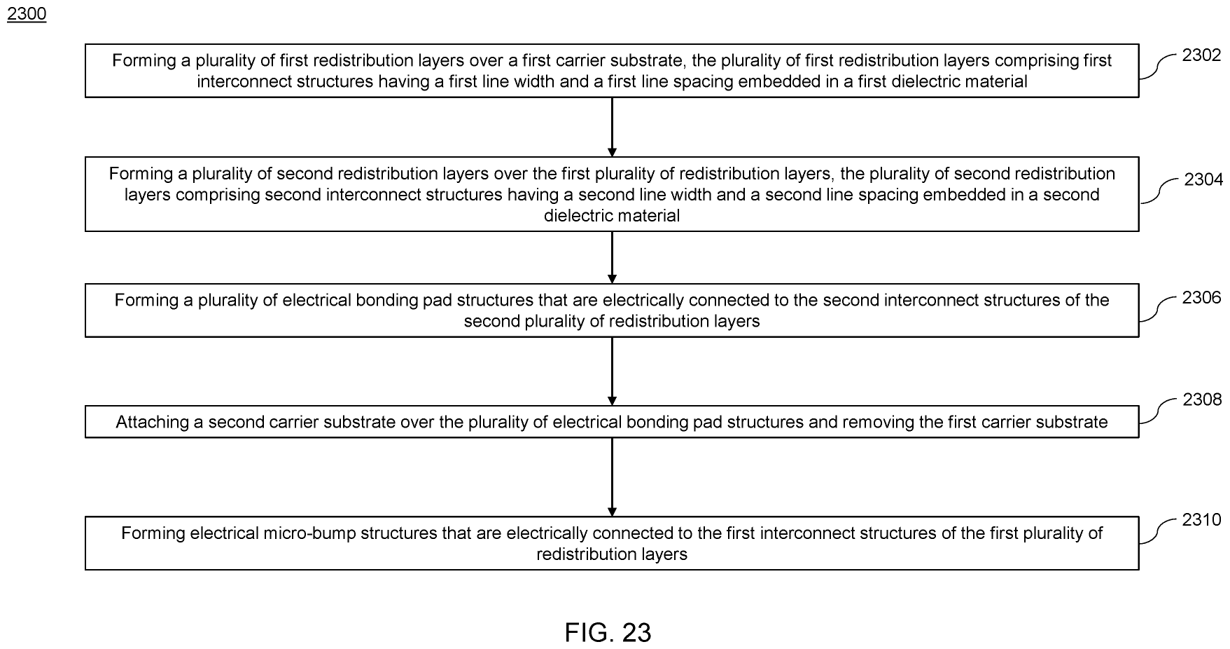

FIG. 23 is a flowchart illustrating various operations of a method 2300 of forming an interposer (e.g., second interposer 108b), according to various embodiments. In operation 2302, the method 2300 may include forming a plurality of first redistribution layers 302a over a first carrier substrate 502a, the plurality of first redistribution layers 302a including first electrical interconnect structures 304a having a first line width and a first line spacing embedded in a first dielectric material 306a. In operation 2304, the method 2300 may include forming a plurality of second redistribution layers 302b over the plurality of first redistribution layers 302a, the plurality of second redistribution layers 302b including second electrical interconnect structures 304b having a second line width and a second line spacing embedded in a second dielectric material 306b. In various embodiments the second line width may be greater than the first line width and the second line spacing may be greater than the first line spacing.

In operation 2306, the method 2300 may include forming a plurality of electrical bonding pad structures 310 that may be electrically connected to the second electrical interconnect structures 304b of the plurality of second redistribution layers 302b. In operation 2308, the method 2300 may include attaching a second carrier substrate 502b over the plurality of electrical bonding pad structures 310 and removing the first carrier substrate 502a. In operation 2310, the method 2300 may include forming electrical micro-bump structures (120, 1102) that may be electrically connected to the first electrical interconnect structures 304a of the plurality of first redistribution layers 302a. According to the method 2300, operation 2302 of forming the plurality of first redistribution layers 302a may further include embedding the first electrical interconnect structures 304a in one of polyimide (PI), benzocyclobutene (BCB), or polybenzo-bisoxazole (PBO). According to the method 2300, operation 2304 of forming the plurality of first redistribution layers 302a may further include embedding the second electrical interconnect 304b structures in an inorganic particulate material dispersed in an epoxy resin.

According to the method 2300, operation 2302 of forming the plurality of first redistribution layers 302a may further include forming a protective layer 312 over the plurality of first redistribution layers 302a such that the protective layer 312 partially surrounds the electrical micro-bump structures (120, 1102). According to various embodiments, the protective layer 312 may be formed of the second dielectric material 306b. According to the method 2300, operation 2304 of forming the plurality of second redistribution layers 302b may further include forming a surface layer 314 over the plurality of second redistribution layers 302b such that the surface layer 314 partially surrounds the plurality of electrical bonding pad structures 310. According to various embodiments, the surface layer 314 may be formed of the first dielectric material 306a.

Referring to all drawings and according to various embodiments of the present disclosure, semiconductor package (300, 300a, 300b, 300c) is provided. The semiconductor package (300, 300a, 300b, 300c) may include an interposer 108b, which may include a plurality of first redistribution layers 302a including first electrical interconnect structures 304a having a first line width and a first line spacing embedded in a first dielectric material 306a and a plurality of second redistribution layers 302b including second electrical interconnect structures 304b having a second line width and a second line spacing embedded in a second dielectric material 306b.

In various embodiments, the second line width may be greater than the first line width and the second line spacing may be greater than the first line spacing. For example, in certain embodiments, the first line width may be between 1 micron and 5 microns and the first line spacing may be between 1 micron and 5 microns. Also, in certain embodiments, the second line width may be between 8 microns and 50 microns and the second line spacing with between 8 microns and 50 microns. In certain embodiments, the first electrical interconnect structures 304a may have a first thickness that may be between 1 micron to 5 microns and the second electrical interconnect structures 304b may have a second thickness that may be between 5 microns and 18 microns.

In various embodiments, the first dielectric material 306a may include a first polymer and the second dielectric material 306b may include an inorganic particulate material dispersed in a second polymer. In some embodiments, the plurality of first redistribution layers 302a may include two to six layers of first electrical interconnect structures 304a embedded in the first dielectric material 306a and the plurality of second redistribution layers 302b may include four to eight layers of second electrical interconnect structures 304b embedded in the second dielectric material 306b. Further, in certain embodiments, the first polymer may include one of PI, BCB, or PBO and the second polymer may include an epoxy resin. The inorganic particulate material may include a silica powder.

In various embodiments, the semiconductor package (300, 300a, 300b, 300c) may further include a semiconductor die (104, 106) electrically connected to the interposer 108b. In various embodiments, the first electrical interconnect structures 304a may be electrically connected to the second electrical interconnect structures 304b such that the interposer 108b may have a slab geometry having a first surface 308a and a second surface 308b that may be parallel to the first surface 308a (e.g., see FIG. 3). The first surface 308a may include electrical micro-bump structures (120, 1102) electrically connected to the first electrical interconnect structures 304a of the of the plurality of first redistribution layers 302a and the second surface 308b may include electrical bonding pad structures 310 electrically connected to the second electrical interconnect structures 304b of the plurality of second redistribution layers 302b. Further, the semiconductor die (104, 106) may be electrically connected to the electrical micro-bump structures.

According to various embodiments, the interposer 108b may further include a protective layer 312 formed over the first surface 308a such that the protective layer 312 may be formed over the plurality of first redistribution layers 302a and may partially surround the electrical micro-bump structures (120, 1102). In various embodiments, the protective layer 312 may be formed of the second dielectric material 306b. In further embodiments, the plurality of second redistribution layers 302b may further include a surface layer 314 formed proximate to the second surface 308b of the interposer 108b such that the surface layer 314 partially surrounds the electrical bonding pad structures 310. The surface layer 314 may be formed of the first dielectric material 306a.

According to a further embodiment, a semiconductor package (300, 300a, 300b, 300c) is provided. The semiconductor package (300, 300a, 300b, 300c) may include an interposer 108b having a slab geometry including a first surface 308a and a second surface 308b. The interposer 108b may further include a plurality of first redistribution layers 302a including first electrical interconnect structures 304a formed in a first dielectric material 306a proximate to the first surface 308a. The interposer 108b may further include a plurality of second redistribution layers 302b including second electrical interconnect structures 304b formed in a second dielectric material 306b proximate to the second surface 308b. In various embodiments, the first dielectric material 306a may have a greater elasticity than the second dielectric material 306b. In certain embodiments, the plurality of second redistribution layers 302b further may include a surface layer 314, including the first dielectric material 306a, formed proximate to the second surface 308b of the interposer 108b such that the surface layer 314 partially surrounds the second electrical interconnect structures 304b.

In various embodiments, the plurality of first redistribution layers 302a may have a first line width that is between 1 micron and 5 microns and a first line spacing is between 1 micron and 5 microns. Similarly, the second redistribution layers 302b may have a second line width that may be between 8 microns and 50 microns and a second line spacing that may be between 8 microns and 50 microns. According to various embodiments, the first dielectric material 306a may include a first polymer that is one of PI, BCB, or PBO, and the second dielectric material 306b may include an inorganic particulate material dispersed in an epoxy resin.

According to various embodiments, the semiconductor package (300, 300a, 300b, 300c) may further include a semiconductor die (104, 106). Further, in some embodiments, the first surface 308a of the interposer 108b may include electrical micro-bump structures (120, 1102) electrically connected to the first electrical interconnect structures 304a of the of the plurality of first redistribution layers 302a. Similarly, the second surface 308b of the interposer 108b may include electrical bonding pad structures 310 electrically connected to the second electrical interconnect structures 304b of the plurality of second redistribution layers 302b. According to various embodiments, the semiconductor die (104, 106) may be electrically connected to the electrical micro-bump structures (120, 1102) in various embodiments.

In certain embodiments, the semiconductor package (300, 300a, 300b, 300c) may further include a protective layer 312 formed over the first surface 308a such that the protective layer 312 is formed over the plurality of first redistribution layers 302a and partially surrounds the electrical micro-bump structures (120, 1102). The protective layer 312 may be formed of the second dielectric material 306b. In various embodiments, the semiconductor package (300, 300a, 300b, 300c) may further include a package substrate (e.g., the second package substrate 110b) electrically connected to the electrical bonding pad structures 310 of the interposer 108b.

A disclosed interposer 108b may be advantageous by providing a plurality of first redistribution layers 302a and a plurality of second redistribution layers 302b. The first redistribution layers 302a may include first electrical interconnect structures 304a having a fine line width and spacing that may be configured to provide high-speed die-to-die (D2D) communication channels between a first semiconductor die 104 and a second semiconductor die 106 in a semiconductor package (300, 300a, 300b, 300c), while the plurality of second redistribution layers 302b may include second electrical interconnect structures 304b that may be configured to provide enhanced power delivery channels relative to those of alternative interposers. Each of the plurality of first electrical interconnect structures 304a and the plurality of second electrical interconnect structures 304b may be formed in one or more polymer materials that may allow increased elastic deformation that may thereby reduce thermal stresses/strains between components of a semiconductor package (300, 300a, 300b, 300c) and may thus mitigate issues related to thermal-induced deformation, warpage, cracking, delamination, etc. The plurality of first redistribution layers 302a may also provide some of the functionality otherwise provided by alternative interposers and the plurality of second redistribution layers 302b may provide some of the functionality otherwise provided by alternative package substrates. As such, a package substrate 110b used in conjunction with the disclosed interposer 108b may require fewer interconnect layers thus leading to an overall reduction in the complexity of the semiconductor package (300, 300a, 300b, 300c) relative to existing package structures.

The foregoing outlines features of several embodiments so that those skilled in the art may better understand the aspects of the present disclosure. Those skilled in the art should appreciate that they may readily use the present disclosure as a basis for designing or modifying other processes and structures for achieving the same purposes and/or the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An semiconductor package, comprising:
an interposer comprising:
a plurality of first redistribution layers comprising first electrical interconnect structures having a first line width and a first line spacing embedded in a first dielectric material; and
a plurality of second redistribution layers comprising second electrical interconnect structures having a second line width and a second line spacing embedded in a second dielectric material,
wherein the second line width is greater than the first line width, and
wherein the second line spacing is greater than the first line spacing.

2. The semiconductor package of claim 1, wherein:
the first line width is between 1 micron and 5 microns; and
the first line spacing is between 1 micron and 5 microns.

3. The semiconductor package of claim 2, wherein:
the second line width is between 8 microns and 50 microns; and
the second line spacing with between 8 microns and 50 microns.

4. The semiconductor package of claim 1, wherein:
the first electrical interconnect structures comprise a first thickness that is between 1 micron to 5 microns; and
the second electrical interconnect structures comprise a second thickness that is between 5 microns and 18 microns.

5. The semiconductor package of claim 1, wherein:
the first dielectric material comprises a first polymer; and
the second dielectric material comprises an inorganic particulate material dispersed in a second polymer.

6. The semiconductor package of claim 5, wherein the plurality of first redistribution layers comprises two to six layers of the first electrical interconnect structures embedded in the first dielectric material.

7. The semiconductor package of claim 5, wherein the plurality of second redistribution layers comprises four to eight layers of the second electrical interconnect structures embedded in the second dielectric material.

8. The semiconductor package of claim 5, wherein the first polymer comprises one of polyimide (PI), benzocyclobutene (BCB), or polybenzo-bisoxazole (PBO).

9. The semiconductor package of claim 5, wherein:
the second polymer comprises an epoxy resin; and
the inorganic particulate material comprises a silica powder.

10. The semiconductor package of claim 5, further comprising a semiconductor die electrically connected to the interposer,
wherein the first electrical interconnect structures are electrically connected to the second electrical interconnect structures such that the interposer comprises a slab geometry having a first surface and a second surface that is parallel to the first surface,
wherein the first surface comprises electrical micro-bump structures electrically connected to the first electrical interconnect structures of the of the plurality of first redistribution layers,
wherein the second surface comprises electrical bonding pad structures electrically connected to the second electrical interconnect structures of the plurality of second redistribution layers, and
wherein the semiconductor die is electrically connected to the electrical micro-bump structures.

11. The semiconductor package of claim 10, further comprising a protective layer comprising the second dielectric material formed over the first surface such that the protective layer is formed over the plurality of first redistribution layers and partially surrounds the electrical micro-bump structures.

12. The semiconductor package of claim 10, wherein the plurality of second redistribution layers further comprises a surface layer comprising the first dielectric material formed proximate to the second surface of the interposer such that the surface layer partially surrounds the electrical bonding pad structures.

13. A semiconductor package, comprising:
an interposer comprising:
a slab geometry comprising a first surface and a second surface;
a plurality of first redistribution layers comprising first electrical interconnect structures formed in a first dielectric material proximate to the first surface;
a plurality of second redistribution layers comprising second electrical interconnect structures formed in a second dielectric material proximate to the second surface,
wherein the first dielectric material has greater elasticity than the second dielectric material, and
wherein the plurality of second redistribution layers further comprises a surface layer comprising the first dielectric material formed proximate to the second surface of the interposer such that the surface layer partially surrounds the second electrical interconnect structures.

14. The semiconductor package of claim 13, wherein:
the plurality of first redistribution layers comprise a first line width is between 1 micron and 5 microns and a first line spacing is between 1 micron and 5 microns;
the plurality of second redistribution layers comprise a second line width is between 8 microns and 50 microns and a second line spacing that is between 8 microns and 50 microns;
the first dielectric material comprises a first polymer that is one of polyimide (PI), benzocyclobutene (BCB), or polybenzo-bisoxazole (PBO); and
the second dielectric material comprises an inorganic particulate material dispersed in an epoxy resin.

15. The semiconductor package of claim 14, further comprising a semiconductor die, wherein:
the first surface comprises electrical micro-bump structures electrically connected to the first electrical interconnect structures of the of the plurality of first redistribution layers;
the second surface comprises electrical bonding pad structures electrically connected to the second electrical interconnect structures of the plurality of second redistribution layers; and
the semiconductor die is electrically connected to the electrical micro-bump structures.

16. The semiconductor package of claim 15, further comprising a protective layer comprising the second dielectric material formed over the first surface such that the protective layer is formed over the plurality of first redistribution layers and partially surrounds the electrical micro-bump structures.

17. The semiconductor package of claim 15, further comprising a package substrate electrically connected to the electrical bonding pad structures of the interposer.

18. A method of forming an interposer, comprising:
forming a plurality of first redistribution layers over a first carrier substrate, the plurality of first redistribution layers comprising first electrical interconnect structures having a first line width and a first line spacing embedded in a first dielectric material; and
forming a plurality of second redistribution layers over the plurality of first redistribution layers, the plurality of second redistribution layers comprising second electrical interconnect structures having a second line width and a second line spacing embedded in a second dielectric material,
wherein the second line width is greater than the first line width, and
wherein the second line spacing is greater than the first line spacing.

19. The method of claim 18, further comprising:
forming a plurality of electrical bonding pad structures that are electrically connected to the second electrical interconnect structures of the plurality of second redistribution layers;
attaching a second carrier substrate over the plurality of electrical bonding pad structures and removing the first carrier substrate; and
forming electrical micro-bump structures that are electrically connected to the first electrical interconnect structures of the plurality of first redistribution layers,
wherein forming the plurality of first redistribution layers further comprises embedding the first electrical interconnect structures in one of polyimide (PI), benzocyclobutene (BCB), or polybenzo-bisoxazole (PBO), and
wherein forming the plurality of second redistribution layers further comprises embedding the second electrical interconnect structures in an inorganic particulate material dispersed in an epoxy resin.

20. The method of claim 19, further comprising:
forming a protective layer, comprising the second dielectric material, over the plurality of first redistribution layers such that the protective layer partially surrounds the electrical micro-bump structures; and
forming a surface layer, comprising the first dielectric material, over the plurality of second redistribution layers such that the surface layer partially surrounds the plurality of electrical bonding pad structures.
